(19) United States
(12) Patent Application Publication
(10) Pub. No.: US 2024/0006217 A1
(43) Pub. Date: Jan. 4, 2024

(54) MICRO LED TRANSFER METHOD, DISPLAY PANEL AND FABRICATION METHOD

(71) Applicant: Shanghai Tianma Micro-Electronics Co., Ltd., Shanghai (CN)

(72) Inventor: Ping ZHU, Shanghai (CN)

(21) Appl. No.: 17/972,071

(22) Filed: Oct. 24, 2022

(30) Foreign Application Priority Data
Jun. 30, 2022 (CN) 202210762566.2

(51) Int. Cl. H01L 21/683; H01L 25/075; H01L 33/62

(52) U.S. Cl. CPC H01L 21/6835; H01L 25/0753; H01L 33/62; H01L 2221/68354; H01L 2221/68368; H01L 2933/0066

(57) ABSTRACT

A Micro LED transfer method, a display panel, and a fabrication method of the display panel are provided. The Micro LED transfer method includes: transferring Micro LEDs of at least two colors from growth substrates thereof to a plurality of first temporary substrates, respectively, where a first temporary substrate includes Micro LEDs of the at least two colors; and transferring the Micro LEDs of the at least two colors located on a same first temporary substrate to at least one array substrate. A same array substrate includes Micro LEDs of the at least two colors, and the Micro LEDs of the at least two colors located on the same array substrate are simultaneously transferred. A distance between adjacent Micro LEDs of a same color on the first temporary substrate is smaller than a distance between adjacent Micro LEDs of the same color on the array substrate.

### CROSS-REFERENCE TO RELATED APPLICATION

This application claims the priority of Chinese patent application No. 202210762566.2, filed on Jun. 30, 2022, the entirety of which is incorporated herein by reference.

### FIELD

The present disclosure generally relates to the field of display technology and, more particularly, relates to a Micro LED transfer method, a display panel and a fabrication method of a display panel.

### BACKGROUND

At present, the display principle of Micro LED display panels is to thin, miniaturize and array the LED structure design to realize the display based on the light emission of the Micro LEDs. Specifically, when fabricating a Micro LED display panel, the Micro LEDs are often first grown on a growth substrate, then the Micro LEDs are peeled off the growth substrate and are transferred to a receiving substrate, and ultimately the Micro LEDs are peeled off the receiving substrate and are transferred to an array substrate. However, in the existing process of transferring the Micro LEDs to the array substrate, the number of transfers is substantially large, and the transfer efficiency and transfer yield are substantially low.

### SUMMARY

One aspect of the present disclosure provides a Micro LED transfer method. The Micro LED transfer method includes transferring Micro LEDs of at least two colors from growth substrates thereof to a plurality of first temporary substrates, respectively. A first temporary substrate of the plurality of first temporary substrates includes Micro LEDs of the at least two colors. The Micro LED transfer method also includes transferring the Micro LEDs of the at least two colors located on a same first temporary substrate to at least one array substrate. A same array substrate of the at least one array substrate includes Micro LEDs of the at least two colors, and the Micro LEDs of the at least two colors located on the same array substrate are simultaneously transferred. A distance between adjacent Micro LEDs of a same color on the first temporary substrate is smaller than a distance between adjacent Micro LEDs of the same color on the array substrate.

Another aspect of the present disclosure provides a fabrication method of a display panel. The display panel includes at least one display unit. The fabrication method includes forming an array substrate, and forming Micro LEDs of various colors on the array substrate by using a Micro LED transfer method to form the display unit. The Micro LED transfer method includes transferring Micro LEDs of at least two colors from growth substrates thereof to a plurality of first temporary substrates, respectively. A first temporary substrate of the plurality of first temporary substrates includes Micro LEDs of the at least two colors. The Micro LED transfer method also includes transferring the Micro LEDs of the at least two colors located on a same first temporary substrate to at least one array substrate. A same array substrate of the at least one array substrate includes Micro LEDs of the at least two colors, and the Micro LEDs of the at least two colors located on the same array substrate are simultaneously transferred. A distance between adjacent Micro LEDs of a same color on the first temporary substrate is smaller than a distance between adjacent Micro LEDs of the same color on the array substrate.

Another aspect of the present disclosure provides a display panel. The display panel is formed by a fabrication method. The fabrication method includes forming an array substrate, and forming Micro LEDs of various colors on the array substrate by using a Micro LED transfer method to form the display unit. The Micro LED transfer method includes transferring Micro LEDs of at least two colors from growth substrates thereof to a plurality of first temporary substrates, respectively. A first temporary substrate of the plurality of first temporary substrates includes Micro LEDs of the at least two colors. The Micro LED transfer method also includes transferring the Micro LEDs of the at least two colors located on a same first temporary substrate to at least one array substrate. A same array substrate of the at least one array substrate includes Micro LEDs of the at least two colors, and the Micro LEDs of the at least two colors located on the same array substrate are simultaneously transferred. A distance between adjacent Micro LEDs of a same color on the first temporary substrate is smaller than a distance between adjacent Micro LEDs of the same color on the array substrate.

Other aspects of the present disclosure can be understood by those skilled in the art in light of the description, the claims, and the drawings of the present disclosure.

### BRIEF DESCRIPTION OF THE DRAWINGS

To more clearly illustrate the embodiments of the present disclosure, the drawings will be briefly described below. The drawings in the following description are certain embodiments of the present disclosure, and other drawings may be obtained by a person of ordinary skill in the art in view of the drawings provided without creative efforts.

FIG. 1 illustrates a schematic diagram of a Micro LED transfer method;

FIG. 2 illustrates a schematic diagram of relative positions of electrodes of a Micro LED during the transfer process in FIG. 1;

FIG. 3 illustrates a schematic flowchart of an exemplary Micro LED transfer method consistent with disclosed embodiments of the present disclosure;

FIG. 4 illustrates a schematic diagram of transferring Micro LEDs of a first color from a growth substrate to a first temporary substrate in an exemplary Micro LED transfer method consistent with disclosed embodiments of the present disclosure;

FIG. 5 illustrates a schematic diagram of transferring Micro LEDs of a second color from a growth substrate to a first temporary substrate in an exemplary Micro LED transfer method consistent with disclosed embodiments of the present disclosure;

FIG. 6 illustrates a schematic diagram of transferring Micro LEDs of a third color from a growth substrate to a first temporary substrate in an exemplary Micro LED transfer method consistent with disclosed embodiments of the present disclosure;

FIG. 7 illustrates a schematic diagram of transferring Micro LEDs of a first color, Micro LEDs of a second color and Micro LEDs of a third color from a first temporary substrate to an array substrate in an exemplary Micro LED transfer method consistent with disclosed embodiments of the present disclosure;

FIG. 8 illustrates a schematic diagram of a Micro LED in an exemplary Micro LED transfer method consistent with disclosed embodiments of the present disclosure;

FIG. 9 illustrates a schematic diagram of transferring Micro LEDs of a first color, Micro LEDs of a second color and Micro LEDs of a third color from a growth substrate to a second temporary substrate in an exemplary Micro LED transfer method consistent with disclosed embodiments of the present disclosure;

FIG. 10 illustrates a schematic diagram of a relative position relationship of electrodes of a Micro LED and a light-emitting structure after transferring Micro LEDs of a first color from a growth substrate to a second temporary substrate in an exemplary Micro LED transfer method consistent with disclosed embodiments of the present disclosure;

FIG. 11 illustrates a schematic diagram of a relative position relationship of electrodes of a Micro LED and a light-emitting structure after transferring Micro LEDs of a second color from a growth substrate to a second temporary substrate in an exemplary Micro LED transfer method consistent with disclosed embodiments of the present disclosure;

FIG. 12 illustrates a schematic diagram of a relative position relationship of electrodes of a Micro LED and a light-emitting structure after transferring Micro LEDs of a third color from a growth substrate to a second temporary substrate in an exemplary Micro LED transfer method consistent with disclosed embodiments of the present disclosure;

FIG. 13 illustrates a schematic diagram of transferring Micro LEDs of a first color from a second temporary substrate to a first temporary substrate in an exemplary Micro LED transfer method consistent with disclosed embodiments of the present disclosure;

FIG. 14 illustrates a schematic diagram of transferring Micro LEDs of a second color from a second temporary substrate to a first temporary substrate in an exemplary Micro LED transfer method consistent with disclosed embodiments of the present disclosure;

FIG. 15 illustrates a schematic diagram of transferring Micro LEDs of a third color from a second temporary substrate to a first temporary substrate in an exemplary Micro LED transfer method consistent with disclosed embodiments of the present disclosure;

FIG. 16 illustrates a schematic diagram of transferring Micro LEDs of a first color from a growth substrate to a second temporary substrate in another exemplary Micro LED transfer method consistent with disclosed embodiments of the present disclosure;

FIG. 17 illustrates a schematic diagram of transferring Micro LEDs of a second color from a growth substrate to a second temporary substrate in another exemplary Micro LED transfer method consistent with disclosed embodiments of the present disclosure;

FIG. 18 illustrates a schematic diagram of transferring Micro LEDs of a third color from a growth substrate to a second temporary substrate in another exemplary Micro LED transfer method consistent with disclosed embodiments of the present disclosure;

FIG. 19 illustrates a schematic diagram of transferring Micro LEDs of a first color, Micro LEDs of a second color and Micro LEDs of a third color from a second temporary substrate to a first temporary substrate in another exemplary Micro LED transfer method consistent with disclosed embodiments of the present disclosure;

FIG. 20 illustrates a schematic diagram of a Micro LED in another exemplary Micro LED transfer method consistent with disclosed embodiments of the present disclosure;

FIG. 21 illustrates a schematic diagram of transferring Micro LEDs of a first color from a growth substrate to a first temporary substrate in another exemplary Micro LED transfer method consistent with disclosed embodiments of the present disclosure;

FIG. 22 illustrates a schematic diagram of a relative position relationship of electrodes of a Micro LED and a light-emitting structure after transferring Micro LEDs of a first color, Micro LEDs of a second color and Micro LEDs of a third color from a growth substrate to a second temporary substrate in another exemplary Micro LED transfer method consistent with disclosed embodiments of the present disclosure;

FIG. 23 illustrates a schematic diagram of transferring Micro LEDs of a second color from a growth substrate to a first temporary substrate in another exemplary Micro LED transfer method consistent with disclosed embodiments of the present disclosure;

FIG. 24 illustrates a schematic diagram of transferring Micro LEDs of a third color from a growth substrate to a first temporary substrate in another exemplary Micro LED transfer method consistent with disclosed embodiments of the present disclosure;

FIG. 25 illustrates a schematic diagram of an arrangement manner of Micro LEDs of at least two colors on a first temporary substrate in an exemplary Micro LED transfer method consistent with disclosed embodiments of the present disclosure;

FIG. 26 illustrates a schematic diagram of an arrangement manner of Micro LEDs of at least two colors on an array substrate in an exemplary Micro LED transfer method consistent with disclosed embodiments of the present disclosure;

FIG. 27 illustrates a schematic diagram of an arrangement manner of Micro LEDs of at least two colors on a first temporary substrate in another exemplary Micro LED transfer method consistent with disclosed embodiments of the present disclosure;

FIG. 28 illustrates a schematic diagram of an arrangement manner of Micro LEDs of at least two colors on an array substrate in another exemplary Micro LED transfer method consistent with disclosed embodiments of the present disclosure;

FIG. 29 illustrates a schematic diagram of an arrangement manner of Micro LEDs of at least two colors on an array substrate in another exemplary Micro LED transfer method consistent with disclosed embodiments of the present disclosure;

FIG. 30 illustrates a schematic diagram of an arrangement manner of Micro LEDs of at least two colors on a first temporary substrate in another exemplary Micro LED transfer method consistent with disclosed embodiments of the present disclosure;

FIG. 31 illustrates a schematic diagram of an arrangement manner of Micro LEDs of at least two colors on an array substrate in another exemplary Micro LED transfer method consistent with disclosed embodiments of the present disclosure; and

FIG. 32 illustrates a schematic diagram of an arrangement manner of Micro LEDs of at least two colors on a first temporary substrate in another exemplary Micro LED transfer method consistent with disclosed embodiments of the present disclosure.

### DETAILED DESCRIPTION OF THE DISCLOSURE

Reference will now be made in detail to exemplary embodiments of the disclosure, which are illustrated in the accompanying drawings. Wherever possible, the same reference numbers will be used throughout the drawings to refer to the same or the alike parts. The described embodiments are some but not all of the embodiments of the present disclosure. Based on the disclosed embodiments, persons of ordinary skill in the art may derive other embodiments consistent with the present disclosure, all of which are within the scope of the present disclosure.

Similar reference numbers and letters represent similar terms in the following Figures, such that once an item is defined in one Figure, it does not need to be further discussed in subsequent Figures.

In the existing process of transferring the Micro LEDs to the array substrate, the number of transfers is substantially large, and the transfer efficiency and transfer yield are substantially low.

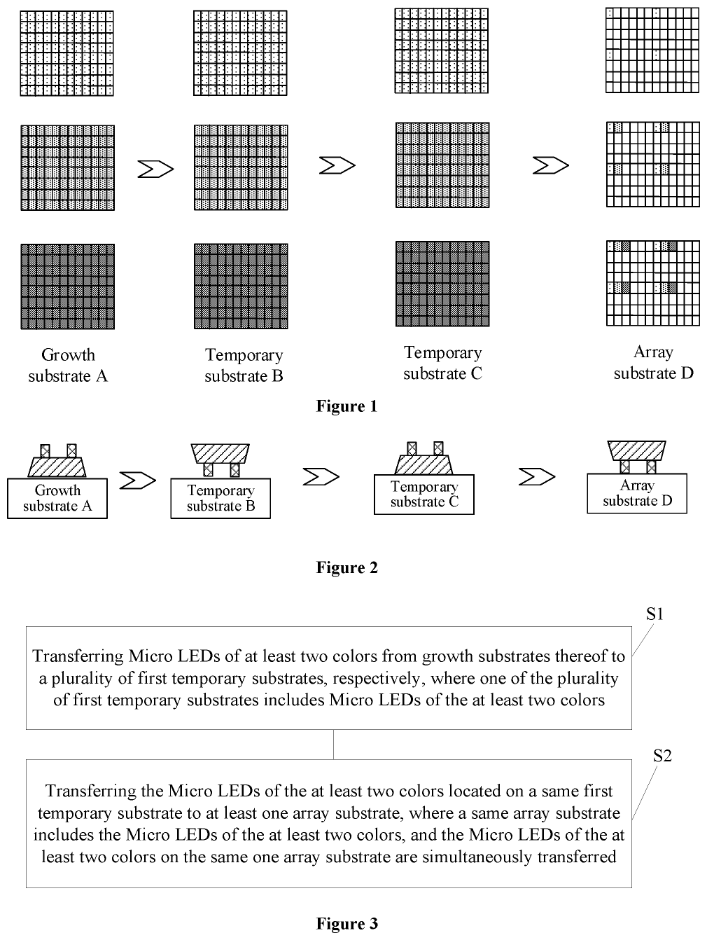

To achieve three-color display of a Micro LED display panel, Micro LEDs of three colors are often formed on the array substrate. The method of transferring the Micro LEDs of three colors to the array substrate includes following. Referring to FIG. 1, Micro LEDs of each single-color are first transferred from a growth substrate A thereof to a corresponding temporary substrate B, such that the Micro LEDs of three colors are transferred to three temporary substrates B through three transfers. Referring to FIG. 2, electrodes of each Micro LED on the growth substrate A face away from the growth substrate A, and the electrodes of each Micro LED on the temporary substrate B face towards the temporary substrate B. Referring to FIG. 1, Micro LEDs of each single-color on the temporary substrate B are transferred to a corresponding temporary substrate C, such that the Micro LEDs of three colors are transferred to three temporary substrates C through three transfers. Referring to FIG. 2, the electrodes of each Micro LED on the temporary substrate C face away from the temporary substrate C. Referring to FIG. 1, Micro LEDs of each single-color on the corresponding temporary substrate C are selectively transferred to an array substrate D, such that the Micro LEDs of three colors are transferred to the array substrate D through three transfers. Referring to FIG. 2, the electrodes of each Micro LED on the array substrate D face towards the array substrate D.

It should be noted that in the above transfer method of Micro LEDs, a total of nine transfers are required to dispose Micro LEDs on the array substrate, the number of transfers is substantially large, and the transfer efficiency is substantially low.

In addition, in the process of transferring Micro LEDs, due to the small size of a Micro LED, the contact area between the Micro LED and the temporary substrate as well as the transfer head is substantially small during the transfer process, which affects the pickup effect of the Micro LED, tends to cause displacement of the Micro LED, and affects the alignment effect. Therefore, in the process of transferring Micro LEDs, the more times transferring the Micro LEDs, the lower the transfer yield.

The present disclosure provides a Micro LED transfer method. Referring to FIG. 3, the transfer method may include following.

S1: transferring Micro LEDs of at least two colors from growth substrates thereof to a plurality of first temporary substrates, respectively, where one of the plurality of first temporary substrates may include Micro LEDs of the at least two colors. In one embodiment, the Micro LEDs of at least two colors may be transferred from the growth substrates thereof to the plurality of first temporary substrates by using a laser process, which may not be limited by the present disclosure and may be determined according to practical applications.

In one embodiment, the Micro LEDs of at least two colors may include Micro LEDs of three colors, which may include Micro LEDs of a first color, Micro LEDs of a second color, and Micro LEDs of a third color, respectively. In another embodiment, the Micro LEDs of at least two colors may include Micro LEDs of other numbers of colors, which may not be limited by the present disclosure, and may be determined according to practical applications.

For illustrative purposes, the Micro LEDs of the at least two colors including the Micro LEDs of three colors may be used as an example to describe the Micro LED transfer method.

In one embodiment, the Micro LEDs of the at least two colors may be transferred from the growth substrates thereof to a plurality of first temporary substrates, respectively, and one of the plurality of first temporary substrates may include Micro LEDs of the at least two colors. The above step may refer to step A, and the step A may include following.

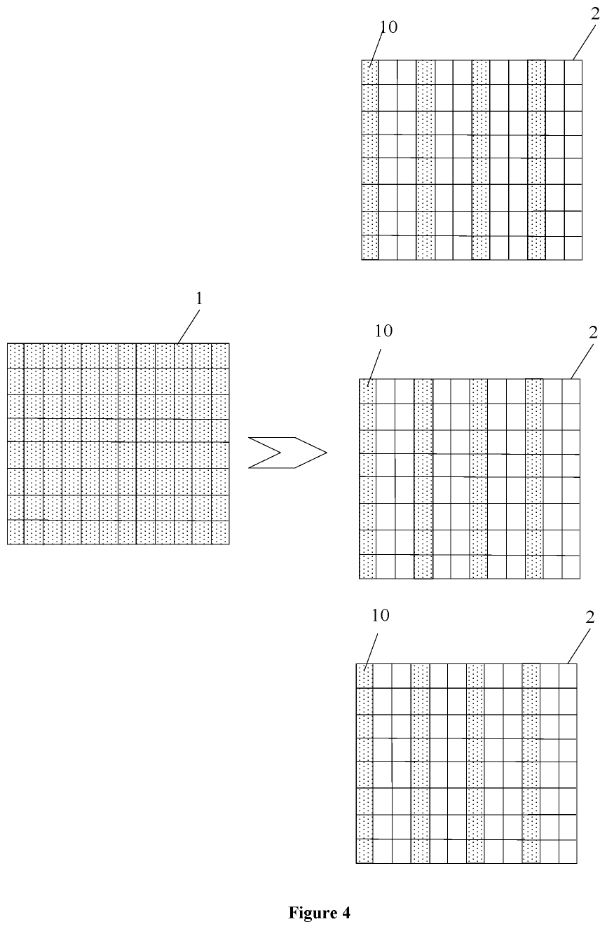

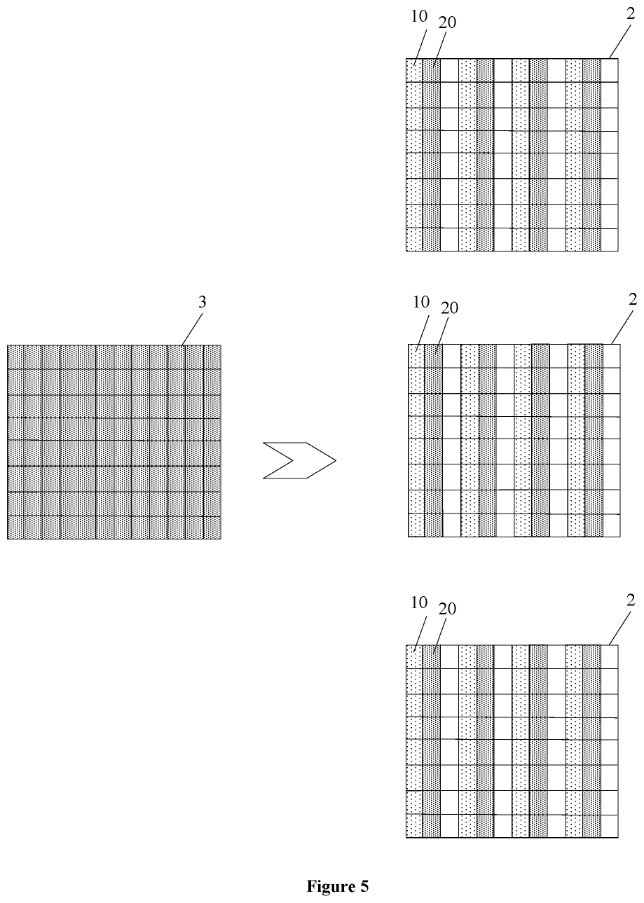

Referring to FIG. 4, Micro LEDs 10 of the first color may be transferred from a growth substrate 1 thereof to a plurality of first temporary substrates 2. In other words, the Micro LEDs 10 of the first color may be transferred from the first growth substrate 1 to the plurality of first temporary substrates 2.

Referring to FIG. 5, Micro LEDs 20 of the second color may be transferred from a growth substrate 3 thereof to the plurality of first temporary substrates 2. In other words, the Micro LEDs 20 of the second color may be transferred from the second growth substrate 3 to the plurality of first temporary substrates 2.

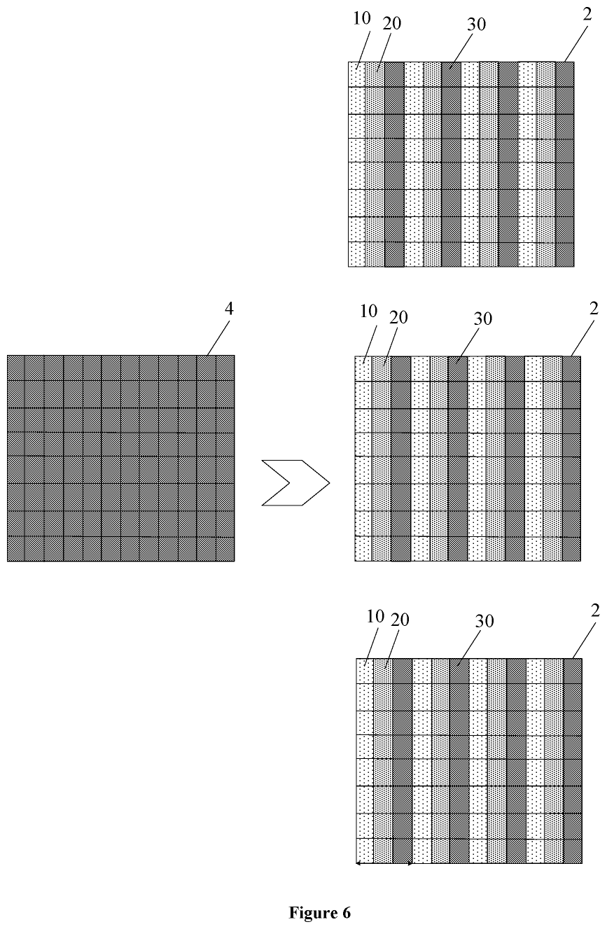

Referring to FIG. 6, Micro LEDs 30 of the third color may be transferred from a growth substrate 4 thereof to the plurality of first temporary substrates 2. In other words, the Micro LEDs 30 of the third color may be transferred from the third growth substrate 4 to the plurality of first temporary substrates 2. Each first temporary substrate 2 may include Micro LEDs of three colors: Micro LEDs 10 of the first color, Micro LEDs 20 of the second color, and Micro LEDs 30 of the third color.

S2: transferring the Micro LEDs of the at least two colors located on a same one first temporary substrate to at least one array substrate, where a same one array substrate may include the Micro LEDs of the at least two colors, and the Micro LEDs of the at least two colors on the same one array substrate may be simultaneously transferred. In one embodiment, the Micro LEDs of the at least two colors on the same one first temporary substrate may be transferred to at least one array substrate by using a laser process, which may not be limited by the present disclosure and may be determined according to practical applications.

In one embodiment, the Micro LEDs of at least two colors may include Micro LEDs of three colors, which may include Micro LEDs of the first color, Micro LEDs of the second color, and Micro LEDs of the third color, respectively. The Micro LEDs of the at least two colors located on the same one first temporary substrate may be transferred to at least one array substrate. The same one array substrate may include Micro LEDs of the at least two colors, and the Micro LEDs of the at least two colors located on the same one array substrate may be simultaneously transferred. The above step may refer to step B, and the step B may include following.

The Micro LEDs of the first color, the Micro LEDs of the second color and the Micro LEDs of the third color on the same one first temporary substrate may be transferred to at least one array substrate, and the Micro LEDs of the first color, the Micro LEDs of the second color and the Micro LEDs of the third color on the same one array substrate may be simultaneously transferred.

In one embodiment, when transferring the Micro LEDs of the at least two colors located on the same one first temporary substrate to one array substrate, the step B may include following.

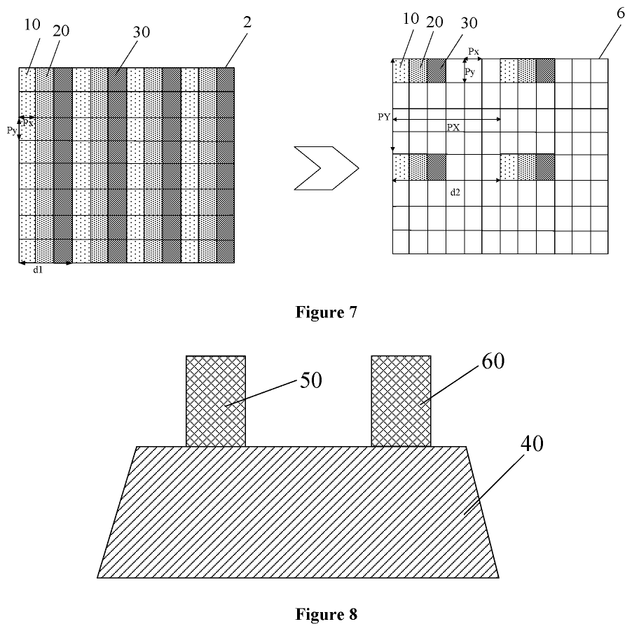

Referring to FIG. 7, the Micro LEDs 10 of the first color, the Micro LEDs 20 of the second color and the Micro LEDs 30 of the third color on the same one first temporary substrate 2 may be simultaneously transferred to the same one array substrate 6.

In another embodiment, when transferring the Micro LEDs of the at least two colors located on the same one first temporary substrate to two array substrates, the step B may include following.

A portion of the Micro LEDs of the first color, a portion of the Micro LEDs of the second color and a portion of the Micro LEDs of the third color on the same one first temporary substrate may be simultaneously transferred to one array substrate. Another portion of the Micro LEDs of the first color, another portion of the Micro LEDs of the second color and another portion of the Micro LEDs of the third color on the same one first temporary substrate may be simultaneously transferred to another one array substrate.

It should be noted that on the basis of the above-disclosed embodiments, referring to FIG. 7, a distance dl between adjacent Micro LEDs of the same color on the first temporary substrate 2 may be smaller than a distance d2 between adjacent Micro LEDs of the same color on the array substrate 6, such that Micro LEDs of the at least two colors located on the same one first temporary substrate 2 may be transferred to at least two array substrates 6.

In one embodiment, transferring the Micro LEDs of the at least two colors located on the same one first temporary substrate to the at least one array substrate may include: transferring the Micro LEDs of the at least two colors located on the same one first temporary substrate to a plurality of array substrates, to reduce the number of transfers corresponding to each array substrate, and to improve the transfer yield and transfer efficiency of the Micro LEDs during the fabrication process of the array substrate.

It should be noted that because the distance between the adjacent Micro LEDs of the same color on the array substrate is much larger than the distance between the adjacent Micro LEDs of the same color on the first temporary substrate, when forming N display panels using the transfer method shown in FIG. 1, transferring the Micro LEDs on the temporary substrate C to the N array substrates may need to be performed 3N times. When forming N display panels using the Micro LED transfer method in the disclosed embodiments, transferring the Micro LEDs on the first temporary substrate to the N array substrates may need to be performed N times. Therefore, the number of transfers may be greatly reduced, and the transfer efficiency and transfer yield may be greatly improved.

It should be noted that in the disclosed Micro LED transfer method, when transferring the Micro LEDs of at least two colors located on the same one first temporary substrate to at least one array substrate, Micro LEDs of the at least two colors required for the array substrate may be located on one first temporary substrate, and the Micro LEDs of the at least two colors located on one first temporary substrate may be simultaneously transferred. Therefore, transferring the Micro LEDs of the at least two colors on the first temporary substrate to the N array substrates may merely need to be performed N times, which may greatly reduce the number of times of transferring the Micro LEDs corresponding to one array substrate. Further, the number of times of transferring the Micro LEDs in the fabrication process of the display panel including the array substrate may be greatly reduced, and the transfer efficiency and transfer yield during the transfer process of the Micro LEDs may be improved.

On the basis of any of the above-disclosed embodiments, in one embodiment, the Micro LED may include a horizontal Micro LED. In one embodiment, referring to FIG. 8, the Micro LED may include a light-emitting structure 40, and a first electrode 50 and a second electrode 60 that are electrically connected to the light-emitting structure 40. The first electrode 50 and the second electrode 60 may be located on a same side of the light-emitting structure 40.

On the basis of the above-disclosed embodiments, in one embodiment, transferring Micro LEDs of the at least two colors from the growth substrates thereof to the plurality of first temporary substrates may include following.

The Micro LEDs of the at least two colors may be transferred from growth substrates thereof to a plurality of second temporary substrates, respectively. On the growth substrate and the second temporary substrate, the Micro LEDs may be arranged according to a first arrangement manner. On the growth substrate, both the first electrode and the second electrode of each Micro LED may be located on the side of the light-emitting structure away from the growth substrate. On the second temporary substrate, both the first electrode and the second electrode of each Micro LED may be located on the side of the light-emitting structure facing towards the second temporary substrate, and each second temporary substrate may merely include Micro LEDs of one color.

The Micro LEDs on each second temporary substrate may be transferred to a plurality of first temporary substrates, each first temporary substrate may include the Micro LEDs of the at least two colors, and the Micro LEDs of the same color on the first temporary substrate may be arranged according to a second arrangement manner. The second arrangement manner may be different from the first arrangement manner. On the first temporary substrate, both the first electrode and the second electrode of each Micro LED may be located on the side of the light-emitting structure facing away from the first temporary substrate.

In one embodiment, the Micro LEDs of the at least two colors may include the Micro LEDs of the first color, the Micro LEDs of the second color and the Micro LEDs of the third color as an example. Respectively transferring the Micro LEDs of the at least two colors from the growth substrates thereof to the plurality of second temporary substrates may include following.

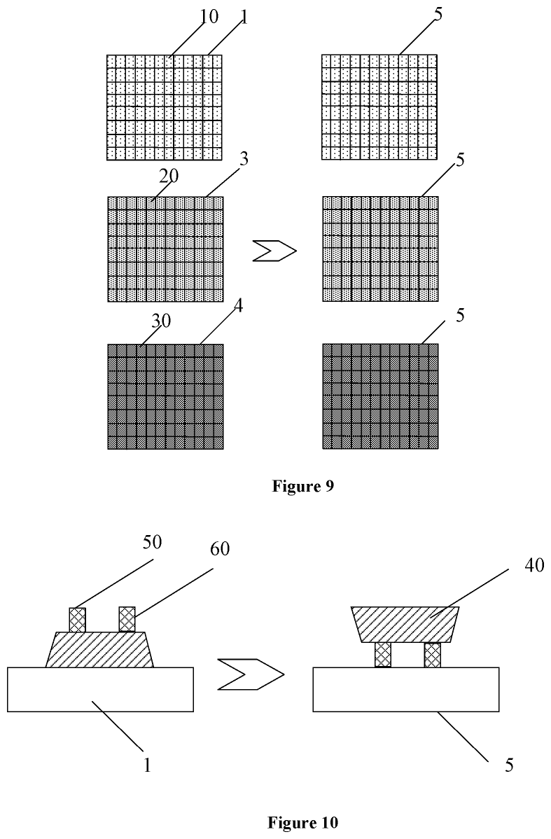

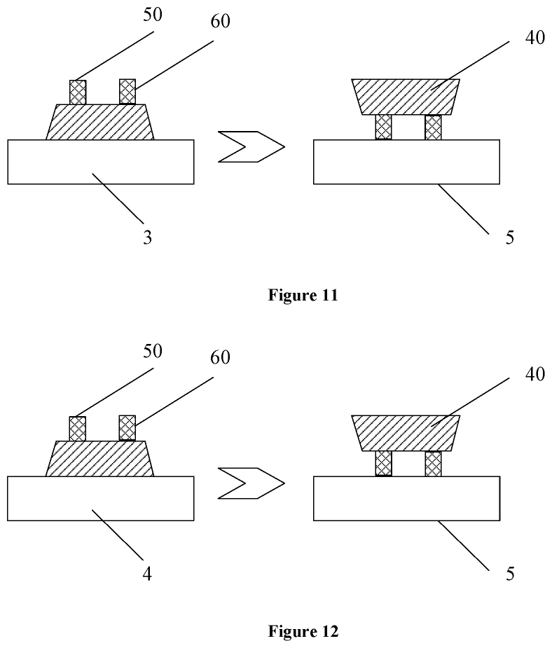

Referring to FIG. 9, the Micro LEDs 10 of the first color may be transferred from the growth substrate 1 thereof to a second temporary substrate 5. In other words, the Micro LEDs 10 of the first color may be transferred from the first growth substrate 1 to the second temporary substrate 5. Referring to FIG. 10, on the growth substrate 1 of the Micro LEDs of the first color, the first electrode 50 and the second electrode 60 of each Micro LED of the first color may be located on the side of the light-emitting structure 40 facing away from the growth substrate 1. On the second temporary substrate 5, the first electrode 50 and the second electrode 60 of each Micro LED of the first color may be located on the side of the light-emitting structure 40 facing towards the second temporary substrate 5.

Referring to FIG. 9, the Micro LEDs 20 of the second color may be transferred from the growth substrate 3 thereof to a second temporary substrate 5. In other words, the Micro LEDs 20 of the second color may be transferred from the second growth substrate 3 to the second temporary substrate 5. Referring to FIG. 11, on the growth substrate 3 of the Micro LEDs of the second color, the first electrode 50 and the second electrode 60 of each Micro LED of the second color may be located on the side of the light-emitting structure 40 facing away from the growth substrate 3. On the second temporary substrate 5, the first electrode 50 and the second electrode 60 of each Micro LED of the second color may be located on the side of the light-emitting structure 40 facing towards the second temporary substrate 5.

Referring to FIG. 9, the Micro LEDs 30 of the third color may be transferred from the growth substrate 4 thereof to a second temporary substrate 5. In other words, the Micro LEDs 30 of the third color may be transferred from the third growth substrate 4 to the second temporary substrate 5. Referring to FIG. 12, on the growth substrate 4 of the Micro LEDs of the third color, the first electrode 50 and the second electrode 60 of each Micro LED of the third color may be located on the side of the light-emitting structure 40 facing away from the growth substrate 4. On the second temporary substrate 5, the first electrode 50 and the second electrode 60 of each Micro LED of the third color may be located on the side of the light-emitting structure 40 facing towards the second temporary substrate 5.

On the basis of the above-disclosed embodiments, in one embodiment, transferring the Micro LEDs on each second temporary substrate to a plurality of first temporary substrates may include following.

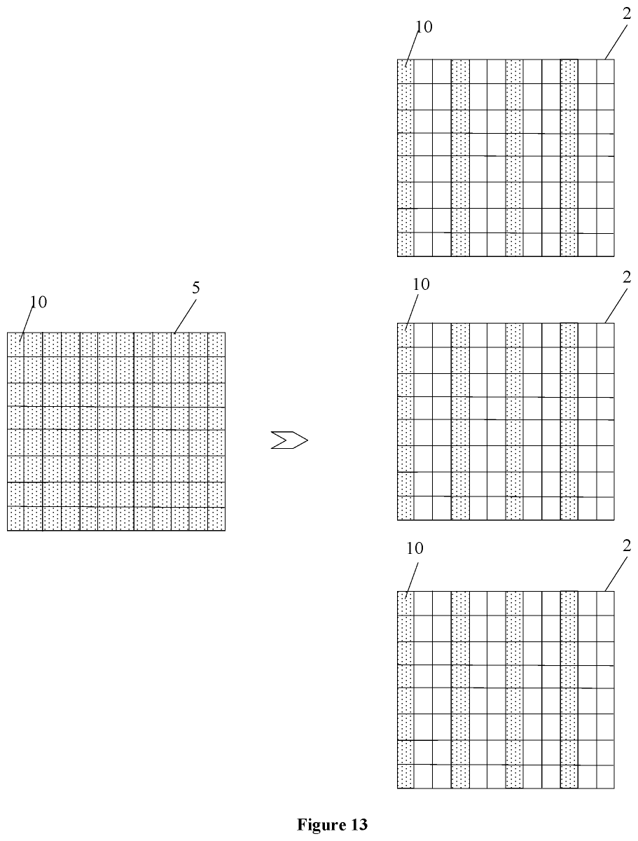

Referring to FIG. 13, the Micro LEDs 10 of the first color may be transferred from the corresponding second temporary substrate 5 to a plurality of first temporary substrates 2. On each first temporary substrate 2, the first electrode and the second electrode of each Micro LED 10 of the first color may be located on the side of the light-emitting structure facing away from the first temporary substrate 2.

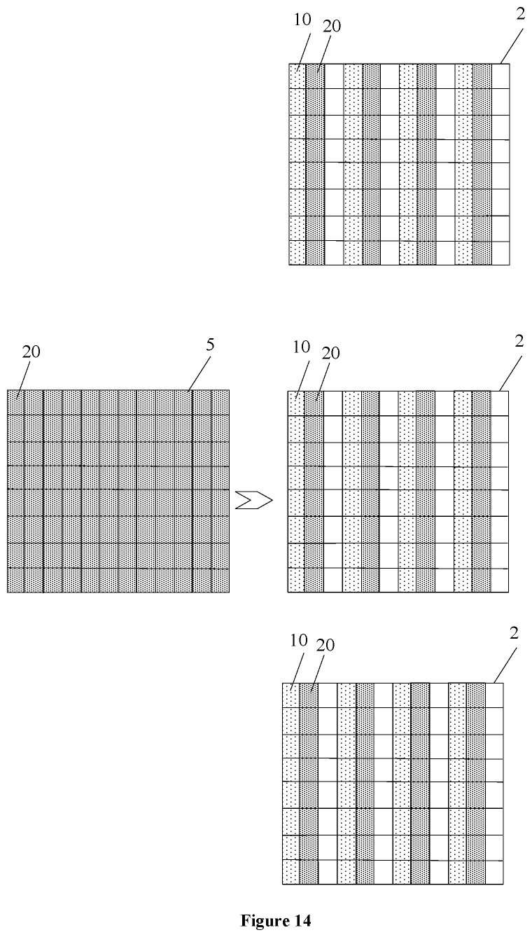

Referring to FIG. 14, the Micro LEDs 20 of the second color may be transferred from the corresponding second temporary substrate 5 to the plurality of first temporary substrates 2. On each first temporary substrate 2, the first electrode and the second electrode of each Micro LED 20 of the second color may be located on the side of the light-emitting structure facing away from the first temporary substrate 2.

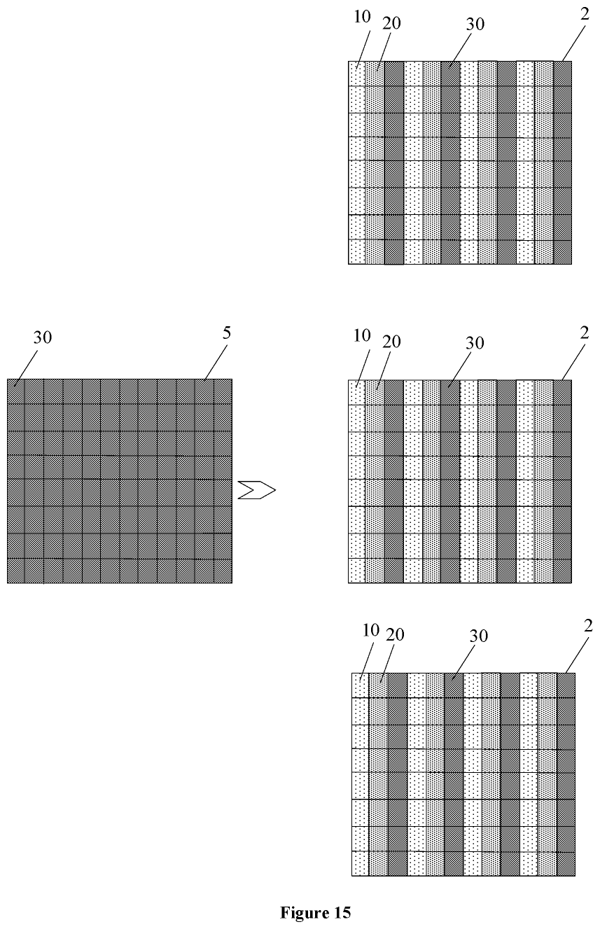

Referring to FIG. 15, the Micro LEDs 30 of the third color may be transferred from the corresponding second temporary substrate 5 to the plurality of first temporary substrates 2. Therefore, each first temporary substrate 2 may include Micro LEDs 10 of the first color, Micro LEDs 20 of the second color, and Micro LEDs 30 of the third color. On each first temporary substrate 2, the first electrode and the second electrode of each Micro LED 30 of the third color may be located on the side of the light-emitting structure facing away from the first temporary substrate 2.

According to the Micro LED transfer method shown in FIG. 1, when forming N

array substrates, transferring the Micro LEDs of three colors from the growth substrates A thereof to the temporary substrates B respectively may require three transfers, transferring the Micro LEDs of three colors from the temporary substrates B to the temporary substrates C respectively may require three transfers, and transferring the Micro LEDs of three colors from the temporary substrates C to the N array substrates respectively may require 3N transfers. Therefore, when forming N array substrates according to the transfer method shown in FIG. 1, transferring the Micro LEDs of three colors from the growth substrates A thereof to the N array substrates may require a total of 3N+3+3 transfers, and each array substrate may correspond to 3+6/N transfers.

When forming N array substrates according to the Micro LED transfer method in the disclosed embodiments, transferring the Micro LEDs of three colors from the growth substrates thereof to the second temporary substrates respectively may require three transfers, transferring the Micro LEDs of three colors from the second temporary substrates to the first temporary substrates respectively may require nine transfers, and transferring the Micro LEDs of three colors from the first temporary substrates to the N array substrates respectively may require N transfers. Therefore, when forming N array substrates according to the Micro LED transfer method in the disclosed embodiments, transferring the Micro LEDs of three colors from the growth substrates thereof to the N array substrates may require a total of 3−9+N transfers, and each array substrate may correspond to (12+N)/N transfers, in other words, each array substrate may correspond to 1+12/N transfers.

Therefore, when N is greater than 3, the number of transfers corresponding to each array substrate in the Micro LED transfer method in the present disclosure may be smaller than the number of transfers corresponding to each array substrate in the transfer method shown in FIG. 1. Further, the larger the value of N is, the more obvious the effect of improving the transfer efficiency and yield of the Micro LED transfer method in the present disclosure is.

Because the array substrates are manufactured in a mass production manner, the Micro LED transfer method in the present disclosure may greatly improve the transfer efficiency and yield of the Micro LEDs.

It should be noted that the display panel to which the array substrates are applied may include a plurality of pixel units, and each pixel unit may include Micro LEDs of various colors among the Micro LEDs of the at least two colors. An area of a sub-pixel region in the display panel occupied by each pixel unit may determine a quantity of array substrates that are capable of being formed by the Micro LEDs on the second temporary substrate.

In one embodiment, on the growth substrate, a spacing between adjacent Micro LEDs in the row direction may be Px, and a spacing between adjacent Micro LEDs in the column direction may be Py.

Referring to FIG. 7, for illustrative purposes, on the first temporary substrate, Micro LEDs of different colors may be cyclically arranged in the row direction as an example. On the first temporary substrate, the spacing between adjacent Micro LEDs in the row direction may be Px, and the spacing between adjacent Micro LEDs in the column direction may be Py. A spacing between adjacent Micro LEDs of the same color in the row direction may be 3Px, and the spacing between adjacent Micro LEDs of the same color in the column direction may be Py.

For illustrative purposes, on the display panel to which the array substrates are applied, one pixel unit (e.g., Micro LEDs of three colors) may occupy 3M*K sub-pixel regions. In other words, one pixel unit in the row direction may occupy an area of 3M sub-pixel regions, and one pixel unit in the column direction may occupy an area of K sub-pixel regions. The spacing between adjacent sub-pixel regions in the row direction may be Px, and the spacing between adjacent sub-pixel regions in the column direction may be Py. On the array substrate, Micro LEDs of different colors may be cyclically arranged in the row direction, and then the spacing between Micro LEDs of the same color in the row direction may be PX=3M*Px, and the spacing between Micro LEDs of the same color in the column direction may be PY=K*Py. A quantity of array substrates that are fabricated from the second temporary substrates may be M*K, and a quantity of array substrates that are fabricated from three second temporary substrates may be 3M*K. A quantity of transfers corresponding to each array substrate may be R=(12+3M*K)/(3M*K), where both M and K may be an integer greater than 1.

It should be noted that in the disclosed embodiments, the area of the second temporary substrate may be the same as the area of the array substrate. The area occupied by a Micro LED on the second temporary substrate may be the same as the area occupied by the sub-pixel region on the array substrate, which may be S=Px*Py. On the second temporary substrate, the area occupied by the Micro LEDs of three colors may be 3Px*Py=3S, and on the array substrate, the area occupied by the Micro LEDs of three colors may be 3MPx*KPy=3M*K*S.

The array substrate may include E sub-pixel regions in the row direction and F sub-pixel regions in the column direction, then the quantity of array substrates that are capable of being fabricated from one second temporary substrate may be

$$\frac{( E * F * S ) / ( 3 * S )}{( E * F * S ) / ( 3 M * K * S )} = M * K ,$$

and the quantity of array substrates that are capable of being fabricated from three second temporary substrates may be 3M*K.

In one embodiment, referring to FIG. 7, M may be 2, K may be 4, and the number of transfers corresponding to each array substrate may be 1.5 times. While using the method shown in FIG. 1, the number of transfers corresponding to each array substrate may be 3.25 times. Therefore, the transfer method in the disclosed embodiments may greatly reduce the number of transfers and may improve the transfer efficiency and transfer yield, which may not be limited by the present disclosure. In certain embodiments, M and K may include other values, which may be determined according to practical applications.

On the basis of any of the above-disclosed embodiments, in one embodiment, the Micro LEDs of the at least two colors may be formed on the growth substrates thereof by an epitaxial process, and the Micro LEDs of the at least two colors may be fixed on the second temporary substrate by a bonding process. A fixing force between the Micro LED and the growth substrate thereof may be greater than a fixing force between the Micro LED and the second temporary substrate. Therefore, in one embodiment, transferring the Micro LEDs from the growth substrate thereof to the second temporary substrate may be carried out in a full-surface transfer manner. In other words, the Micro LEDs of each color among the Micro LEDs of the at least two colors may be simultaneously transferred from the growth substrate thereof to the corresponding second temporary substrate, and each second temporary substrate may merely include Micro LEDs of one color, to reduce the difficulty of the process of simultaneously transferring of the Micro LEDs of the at least two colors from the growth substrates thereof to the second temporary substrate, respectively, which may not be limited by the present disclosure. In certain embodiments, each second temporary substrate may include the Micro LEDs of the at least two colors, which may be determined according to practical applications.

The Micro LEDs of the at least two colors may be transferred from the growth substrates thereof to a plurality of first temporary substrates, and one first temporary substrate may include Micro LEDs of the at least two colors, which may refer to step A. In another embodiment, each second temporary substrate may further include Micro LEDs of the at least two colors. The step A may include following.

The Micro LEDs of the at least two colors may be transferred from growth substrates thereof to a plurality of second temporary substrates, respectively, and each second temporary substrate may include Micro LEDs of the at least two colors. The Micro LEDs of a same color may be arranged according to the first arrangement manner on the growth substrate, and may be arranged according to the second arrangement manner on the second temporary substrate. The first arrangement manner may be different from the second arrangement manner. On the growth substrate, both the first electrode and the second electrode of each Micro LED may be located on the side of the light-emitting structure facing away from the growth substrate. On the second temporary substrate, both the first electrode and the second electrode of each Micro LED may be located on the side of the light-emitting structure facing towards the second temporary substrate.

The Micro LEDs on each second temporary substrate may be transferred to a plurality of first temporary substrates, each first temporary substrate may include Micro LEDs of the at least two colors, and the Micro LEDs of the same color on the first temporary substrate may be arranged according to the second arrangement manner. On the first temporary substrate, both the first electrode and the second electrode of each Micro LED may be located on the side of the light-emitting structure facing away from the first temporary substrate.

In one embodiment, for illustrative purposes, the Micro LEDs of the at least two colors may include Micro LEDs of the first color, Micro LEDs of the second color, and Micro LEDs of the third color as an example. The step A may include following.

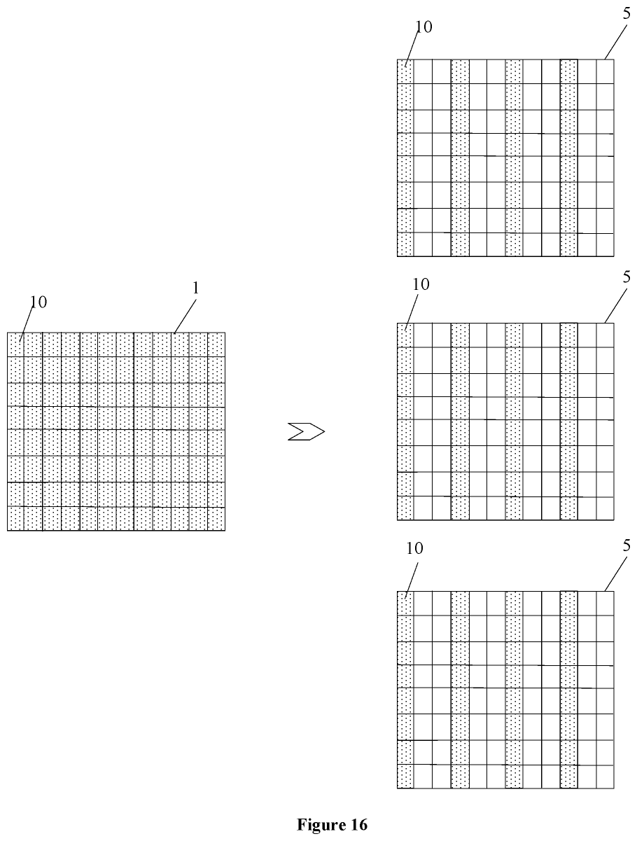

Referring to FIG. 16, Micro LEDs 10 of the first color may be transferred from the growth substrate 1 thereof to a plurality of second temporary substrates 5. In other words, the Micro LEDs 10 of the first color may be transferred from the first growth substrate 1 to the plurality of second temporary substrates 5. On the first growth substrate 1 of the Micro LEDs of the first color, the first electrode 50 and the second electrode 60 of each Micro LED of the first color may be located on the side of the light-emitting structure 40 facing away from the first growth substrate 1. On the second temporary substrate 5, the first electrode 50 and the second electrode 60 of each Micro LED of the first color may be located on the side of the light-emitting structure 40 facing towards the second temporary substrate 5.

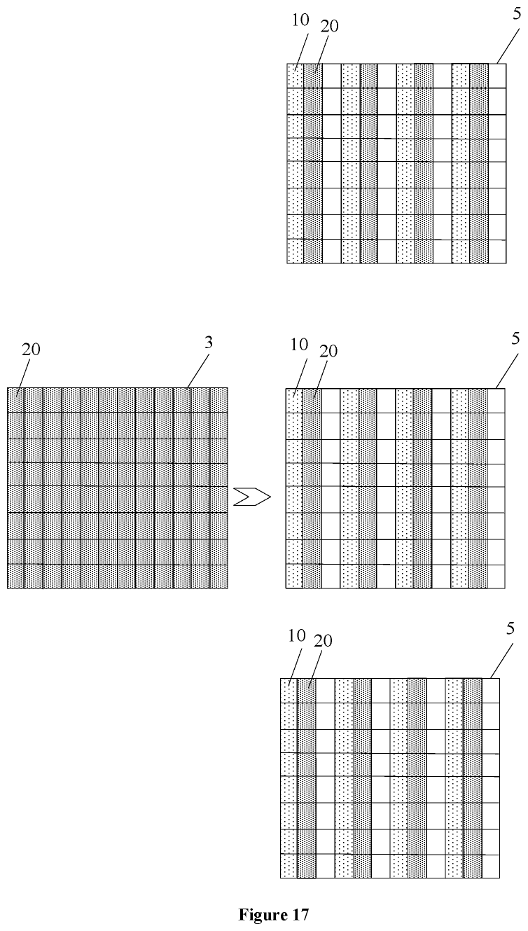

Referring to FIG. 17, Micro LEDs 20 of the second color may be transferred from the growth substrate 3 thereof to the plurality of second temporary substrates 5. In other words, the Micro LEDs 20 of the second color may be transferred from the second growth substrate 3 to the plurality of second temporary substrates 5. On the growth substrate 3 of the Micro LEDs of the second color, the first electrode 50 and the second electrode 60 of each Micro LED of the second color may be located on the side of the light-emitting structure 40 facing away from the growth substrate 3. On the second temporary substrate 5, the first electrode 50 and the second electrode 60 of each Micro LED of the second color may be located on the side of the light-emitting structure 40 facing towards the second temporary substrate 5.

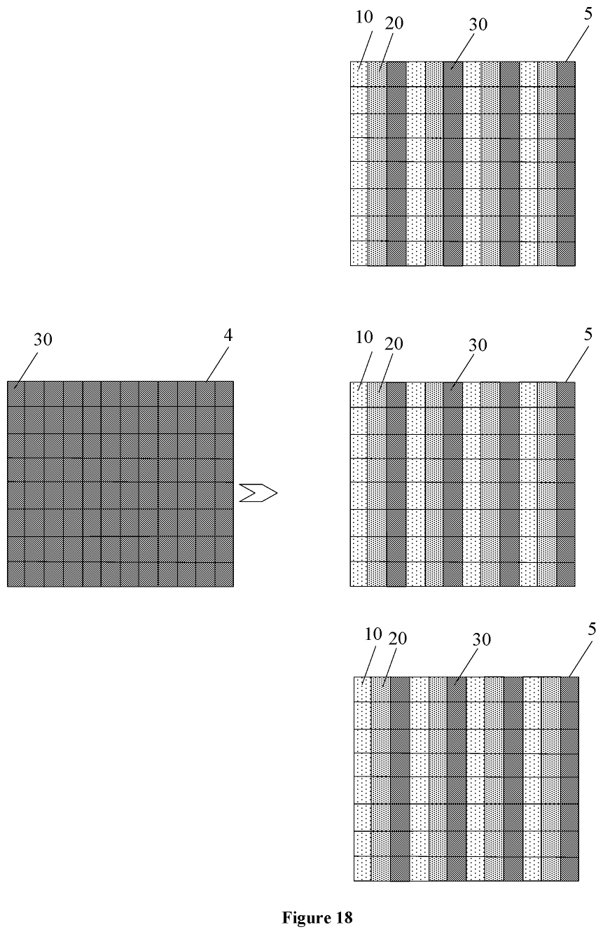

Referring to FIG. 18, Micro LEDs 30 of the third color may be transferred from the growth substrate 4 thereof to the plurality of second temporary substrates 5. In other words, the Micro LEDs 30 of the third color may be transferred from the third growth substrate 4 to the plurality of second temporary substrates 5. On the growth substrate 4 of the Micro LEDs of the third color, the first electrode 50 and the second electrode 60 of each Micro LED of the third color may be located on the side of the light-emitting structure 40 facing away from the growth substrate 4. On the second temporary substrate 5, the first electrode 50 and the second electrode 60 of each Micro LED of the third color may be located on the side of the light-emitting structure 40 facing towards the second temporary substrate 5.

On the basis of the above-disclosed embodiments, in one embodiment, transferring Micro LEDs of the at least two colors from each second temporary substrate to the plurality of first temporary substrates may include following.

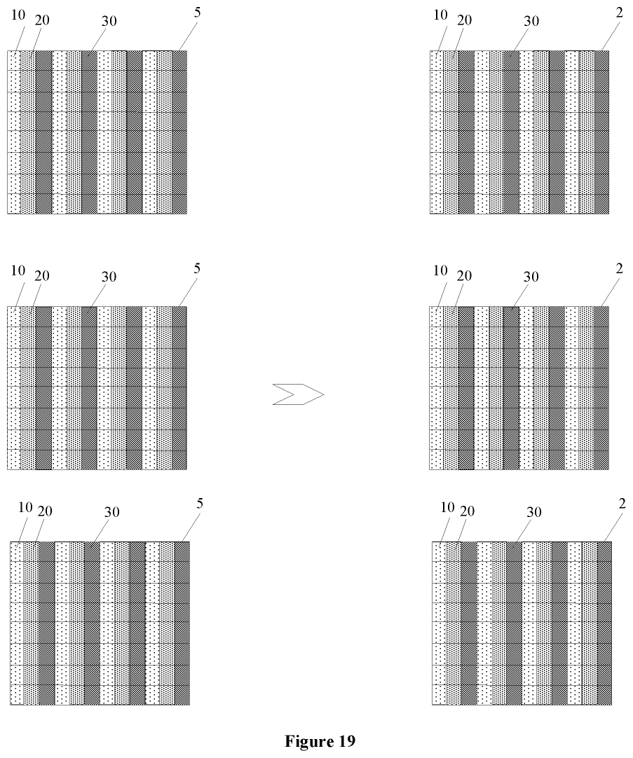

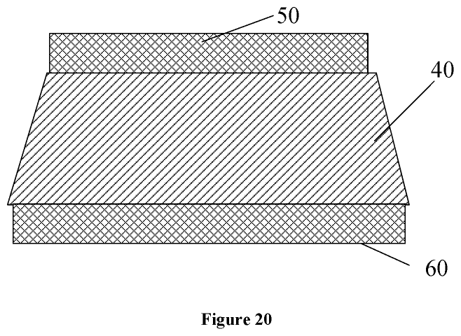

Referring to FIG. 19, the Micro LEDs 10 of the first color, the Micro LEDs 20 of the second color and the Micro LEDs 30 of the third color may be transferred from the plurality of second temporary substrates 5 to the plurality of first temporary substrates 2. On the first temporary substrate 2, the first electrode and the second electrode of each Micro LED 10 of the first color may be located on the side of the light-emitting structure facing away from the first temporary substrate 2, the first electrode and the second electrode of each Micro LED 20 of the second color may be located on the side of the light-emitting structure facing away from the first temporary substrate 2, and the first electrode and the second electrode of each Micro LED 30 of the third color may be located on the side of the light-emitting structure facing away from the first temporary substrate 2.

In another embodiment, the Micro LED may be a vertical Micro LED. In one embodiment, referring to FIG. 20, the Micro LED may include the light-emitting structure 40, and a first electrode 50 and a second electrode 60 that are electrically connected to the first light-emitting structure 40. The first electrode 50 and the second electrode 60 may be located on opposite sides of the light-emitting structure 40.

On the basis of the above-disclosed embodiments, in one embodiment, the Micro LEDs of the at least two colors may be transferred from the growth substrates thereof to a plurality of first temporary substrates, respectively, and one of the plurality of first temporary substrates may include Micro LEDs of the at least two colors. The above step may refer to step A, and the step A may include following.

The Micro LEDs of the at least two colors may be transferred from growth substrates thereof to the plurality of first temporary substrates, respectively, and each first temporary substrate may include Micro LEDs of the at least two colors. The Micro LEDs of a same color may be arranged according to the first arrangement manner on the growth substrate, and may be arranged according to the second arrangement manner on the first temporary substrate. The first arrangement manner may be different from the second arrangement manner. On the growth substrate, the first electrode of each Micro LED may be located on the side of the light-emitting structure facing towards the growth substrate, and the second electrode of each Micro LED may be located on the side of the light-emitting structure facing away from the growth substrate. On the first temporary substrate, the first electrode of each Micro LED may be located on the side of the light-emitting structure facing away from the first temporary substrate, and the second electrode of each Micro LED may be located on the side of the light-emitting structure facing towards the first temporary substrate.

In one embodiment, for illustrative purposes, the Micro LEDs of the at least two colors may include Micro LEDs of the first color, Micro LEDs of the second color, and Micro LEDs of the third color as an example. The step A may include following.

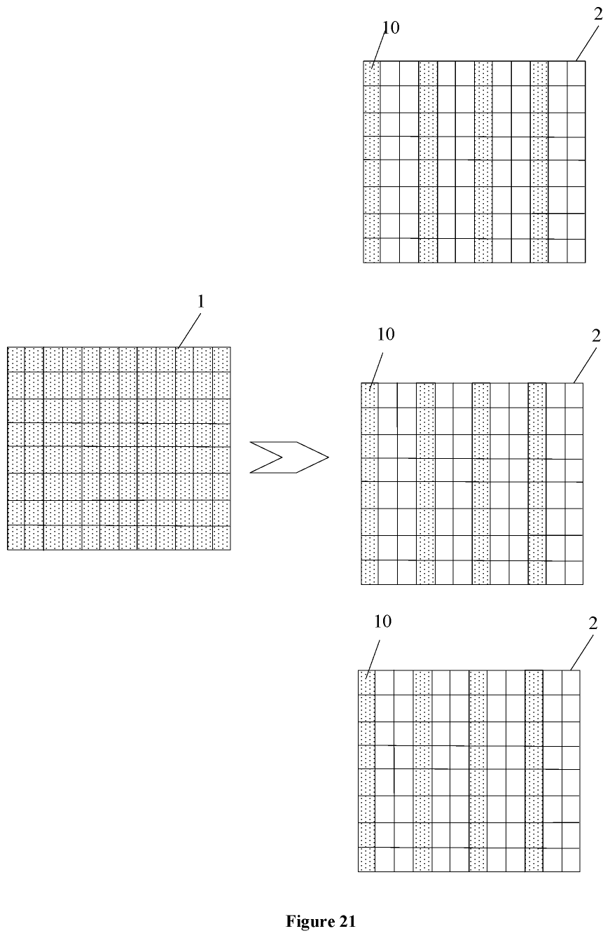

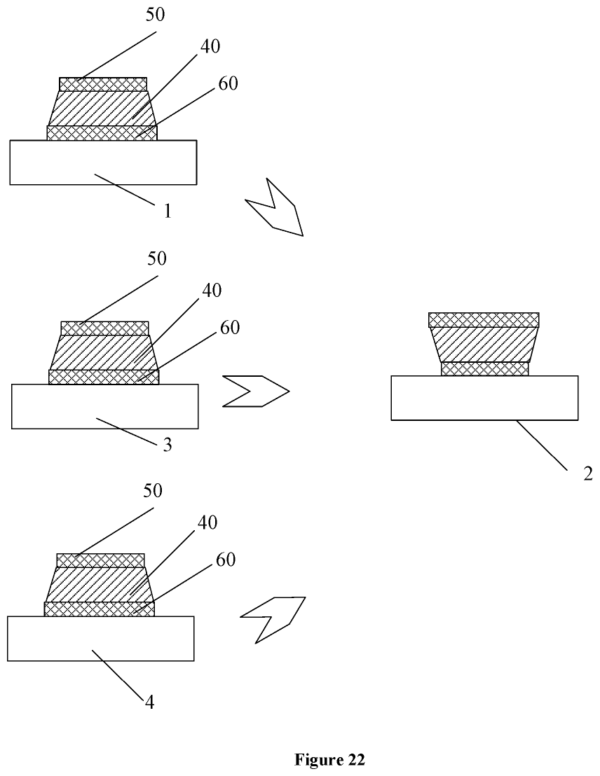

Referring to FIG. 21, Micro LEDs 10 of the first color may be transferred from the growth substrate 1 thereof to a plurality of first temporary substrates 2. In other words, the Micro LEDs 10 of the first color may be transferred from the first growth substrate 1 to the plurality of first temporary substrates 2. Referring to FIG. 22, on the first growth substrate 1 of the Micro LEDs 10 of the first color, the first electrode 50 of each Micro LED of the first color may be located on the side of the light-emitting structure 40 facing away from the first growth substrate 1, and the second electrode 60 of each Micro LED of the first color may be located on the side of the light-emitting structure 40 facing towards the first growth substrate 1. On the first temporary substrate 2, the first electrode 50 of each Micro LED of the first color may be located on the side of the light-emitting structure 40 facing towards the first temporary substrate 2, and the second electrode 60 of each Micro LED of the first color may be located on the side of the light-emitting structure 40 facing away from the first temporary substrate 2.

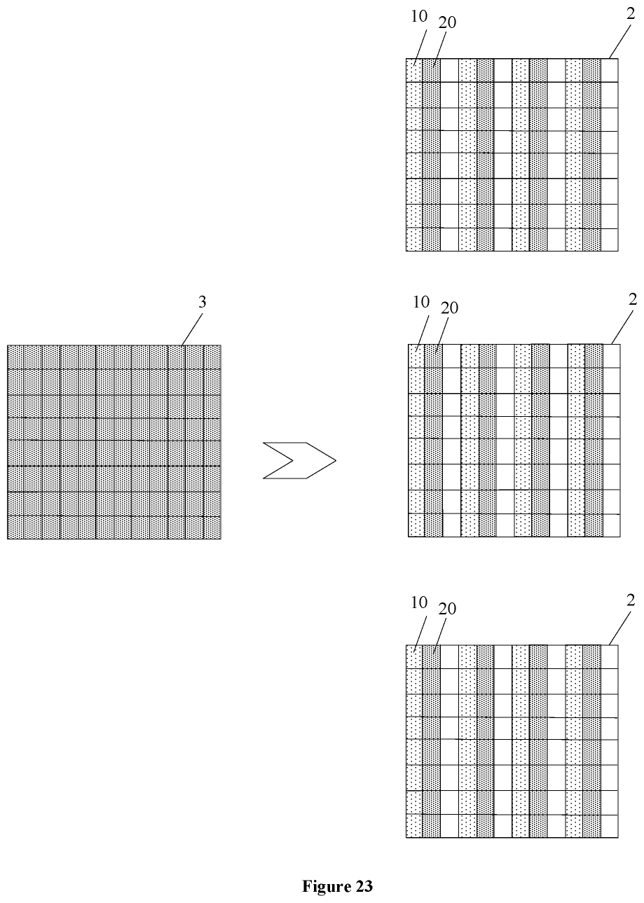

Referring to FIG. 23, Micro LEDs 20 of the second color may be transferred from the growth substrate 3 thereof to the plurality of first temporary substrates 2. In other words, the Micro LEDs 20 of the second color may be transferred from the second growth substrate 3 to the plurality of first temporary substrates 2. Referring to FIG. 22, on the growth substrate 3 of the Micro LEDs of the second color, the first electrode 50 of each Micro LED of the second color may be located on the side of the light-emitting structure 40 facing away from the growth substrate 3, and the second electrode 60 of each Micro LED of the second color may be located on the side of the light-emitting structure 40 facing towards the growth substrate 3. On the first temporary substrate 2, the first electrode 50 of each Micro LED of the second color may be located on the side of the light-emitting structure 40 facing towards the first temporary substrate 2, and the second electrode 60 of each Micro LED of the second color may be located on the side of the light-emitting structure 40 facing away from the first temporary substrate 2.

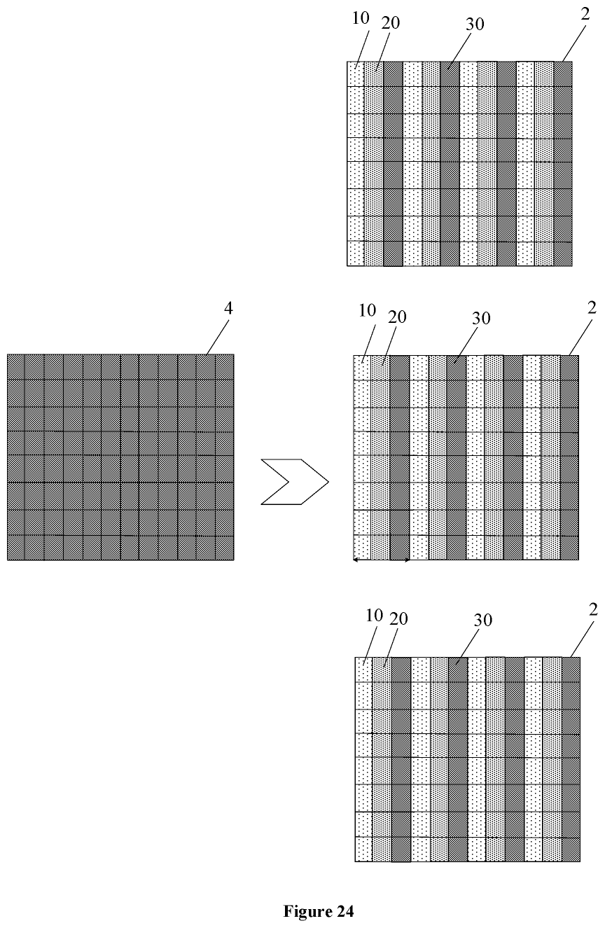

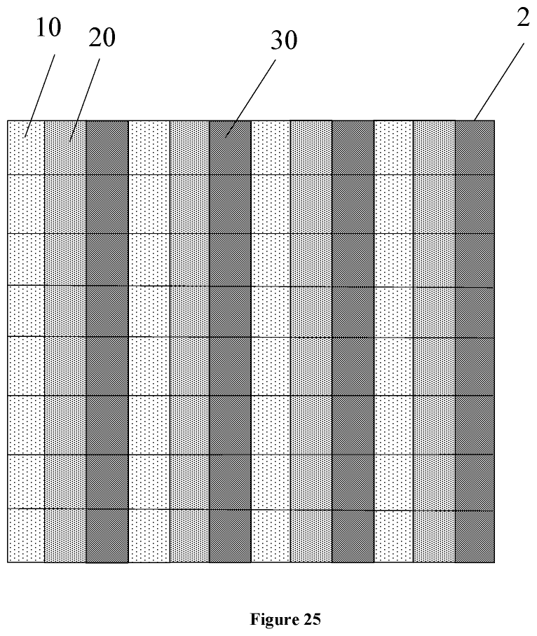

Referring to FIG. 24, Micro LEDs 30 of the third color may be transferred from the growth substrate 4 thereof to the plurality of first temporary substrates 2. In other words, the Micro LEDs 30 of the third color may be transferred from the third growth substrate 4 to the plurality of first temporary substrates 2. Each first temporary substrate 2 may include Micro LEDs 10 of the first color, Micro LEDs 20 of the second color, and Micro LEDs 30 of the third color. Referring to FIG. 22, on the growth substrate 4 of the Micro LEDs of the third color, the first electrode 50 of each Micro LED of the third color may be located on the side of the light-emitting structure 40 facing away from the growth substrate 4, and the second electrode 60 of each Micro LED of the third color may be located on the side of the light-emitting structure 40 facing towards the growth substrate 4. On the first temporary substrate 2, the first electrode 50 of each Micro LED of the third color may be located on the side of the light-emitting structure 40 facing towards the first temporary substrate 2, and the second electrode 60 of each Micro LED of the third color may be located on the side of the light-emitting structure 40 facing away from the first temporary substrate 2.

On the basis of any of the above-disclosed embodiments, in one embodiment, in the second arrangement manner, the Micro LEDs of the at least two colors may include a plurality of columns of Micro LEDs arranged in a row direction. At least a portion of adjacent columns of Micro LEDs in the plurality of columns of Micro LEDs may include Micro LEDs of different colors.

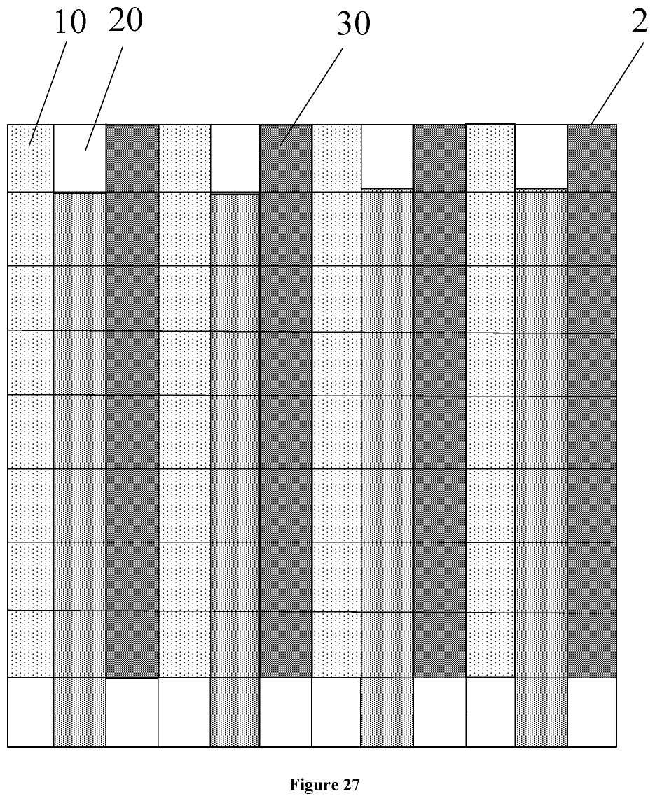

On the basis of the above-disclosed embodiments, in one embodiment, referring to FIG. 25 and FIG. 27, the Micro LEDs of the at least two colors may include a plurality of columns of Micro LEDs arranged in the row direction. Any two adjacent columns of Micro LEDs in the plurality of columns of Micro LEDs may include Micro LEDs of different colors. In other words, the Micro LEDs in the first column and the Micro LEDs in the second column may include Micro LEDs with different colors. The Micro LEDs in the second column and the Micro LEDs in the third column may include Micro LEDs of different colors. The Micro LEDs in the third column and the Micro LEDs in the fourth column may include Micro LEDs of different colors. Similarly, the Micro LEDs in the j^{th} column and the Micro LEDs in the (j+1)^{th} column may include Micro LEDs of different colors, where j may be a positive integer greater than three.

On the basis of the above-disclosed embodiments, in one embodiment, referring

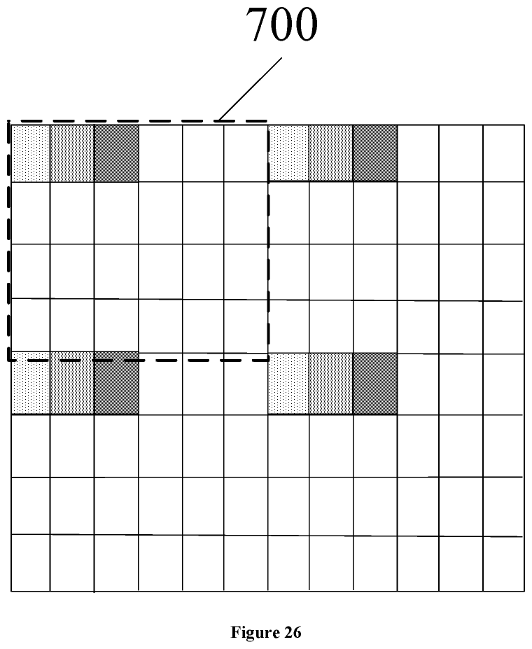

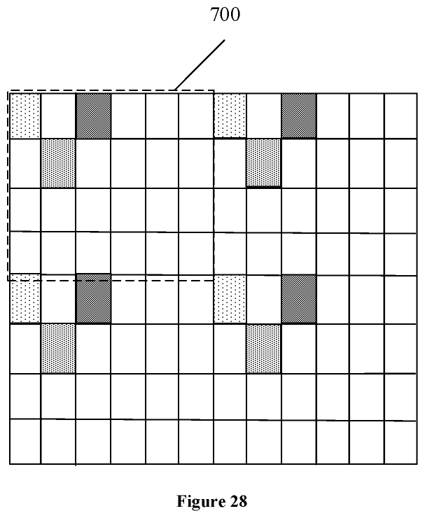

to FIG. 26 and FIG. 28, the array substrate may include a plurality of repeating units 700. One repeating unit 700 may correspond to one pixel unit in the array substrate. In one embodiment, a ratio of quantities of Micro LEDs of each color in each repeating unit 700 may be 1:1:1. In one embodiment, each repeating unit 700 may include one Micro LED of the first color, one Micro LED of the second color and one Micro LED of the third color, such that each pixel unit may display independently. In one embodiment, the Micro LEDs located in a same column in the plurality of columns of Micro LEDs may include Micro LEDs of the same color, which may not be limited by the present disclosure, and may be determined according to practical applications.

On the basis of the above-disclosed embodiments, in one embodiment, referring to FIG. 25, two adjacent columns of Micro LEDs in the plurality of columns of Micro LEDs may be substantially center-to-center aligned in the row direction. In other words, in the column direction, the i^{th} Micro LED of each color in the Micro LEDs of the at least two colors may be arranged in the same row, where i may be a positive integer greater than or equal to one. In one embodiment, the plurality of columns of Micro LEDs may include j^{th} column of Micro LEDs and (j+1)^{th} column of Micro LEDs. The j^{th} column of Micro LEDs and the (j+1)^{th} column of Micro LEDs may be any two adjacent columns of Micro LEDs in the plurality of columns of Micro LEDs. The i^{th} Micro LED in the i^{th} column of Micro LEDs and the i^{th} Micro LED in the (j+1)^{th} column of Micro LEDs may be located in the same row, where j may be any integer greater than or equal to one.

In one embodiment, the i^{th} column of Micro LEDs may include Micro LEDs of the first color, and the (j+1)^{th} column of Micro LEDs may include Micro LEDs of the second color. In another embodiment, the i^{th} column of Micro LEDs may include Micro LEDs of the second color, and the (j+1)^{th} column of Micro LEDs may include Micro LEDs of the third color. In certain embodiments, the i^{th} column of Micro LEDs may include Micro LEDs of the third color, and the (j+1)^{th} column of Micro LEDs may include Micro LEDs of the first color, which may not be limited by the present disclosure, and may be determined according to practical applications.

In another embodiment, in the plurality of columns of Micro LEDs, the i^{th} Micro LEDs arranged in the column direction of the Micro LEDs of at least two colors may be located in different rows, and the i^{th} Micro LEDs arranged in the column direction of the Micro LEDs of a same color may be located in the same row, where i may be a positive integer greater than or equal to one, which may not be limited by the present disclosure. In another embodiment, in the second arrangement manner, the Micro LEDs of the at least two colors may be arranged in any other way, which may be determined according to practical applications.

In one embodiment, referring to FIG. 27, in the second arrangement manner, the Micro LEDs of the at least two colors may include Micro LEDs of the first color, Micro LEDs of the second color, and Micro LEDs of the third color that are arranged in the row direction. The Micro LEDs of the second color may be located between the Micro LEDs of the first color and the Micro LEDs of the third color.

In the column direction, the i^{th} Micro LED of the Micro LEDs of the first color and the i^{th} Micro LED of the Micro LEDs of the third color may be located in the same row, and the i^{th} Micro LED of the Micro LEDs of the first color and the i^{th} Micro LED of the Micro LEDs of the second color may be located in the same row, where i may be a positive integer greater than or equal to one.

In one embodiment, the plurality of columns of Micro LEDs may include (3j+1)^{th} column of Micro LEDs, (3j+2)^{th} column of Micro LEDs and (3j+3)^{th} column of Micro LEDs, where j may be an integer greater than or equal to zero. The (3j+1)^{th} column of Micro LEDs and (3j+2)^{th} column of Micro LEDs may be two adjacent columns of Micro LEDs in the plurality of columns of Micro LEDs, and the (3j+2)^{th} column of Micro LEDs and (3j+3)^{th} column of Micro LEDs may be two adjacent columns of Micro LEDs in the plurality of columns of Micro LEDs. The (3j+1)^{th} column of Micro LEDs may include Micro LEDs of the first color, the (3j+2)^{th} column of Micro LEDs may include Micro LEDs of the second color, and the (3j+3)^{th} column of Micro LEDs may include Micro LEDs of the third color. The i^{th} Micro LEDs of at least two columns of the Micro LEDs among the (3j+1)^{th} column of Micro LEDs, the (3j+2)^{th} column of Micro LEDs and the (3j+3)^{th} column of Micro LEDs may be located in different rows. In one embodiment, the i th Micro LED of the (3j+1)^{th} column of Micro LEDs and the i th Micro LED of the (3j+2)^{th} column of Micro LEDs may be located in different rows. In another embodiment, the i^{th} Micro LED of the (3j+2)^{th} column of Micro LEDs and the i^{th} Micro LED of the (3j+3)^{th} column of Micro LEDs may be located in different rows. In certain embodiments, the i^{th} Micro LED of the (3j+3)^{th} column of Micro LEDs and the i^{th} Micro LED of the (3j+1)^{th} column of Micro LEDs may be located in different rows, which may not be limited by the present disclosure, and may be determined according to practical applications.

On the basis of the above-disclosed embodiments, in one embodiment, referring to FIG. 27, the i^{th} Micro LED of the (3j+1)^{th} column of Micro LEDs and the i^{th} Micro LED of the (3j+2)^{th} column of Micro LEDs may be located in different rows, and the i^{th} Micro LED of the (3j+l)^{th} column of Micro LEDs and the i^{th} Micro LED of the (3j+3)^{th} column of Micro LEDs may be located in a same row. In other words, the first Micro LED of the Micro LEDs of the first color and the first Micro LED of the Micro LEDs of the third color may be located in the same row, and the second Micro LED of the Micro LEDs of the first color and the first Micro LED of Micro LEDs of the second color may be located in the same row.

In other words, the first Micro LED of Micro LEDs of the first color may be located in the first row, the second Micro LED of Micro LEDs of the first color may be located in the second row, and so on, the n th Micro LED of Micro LEDs of the first color may be located in the n^{th} row. The first Micro LED of Micro LEDs of the second color may be located in the second row, the second Micro LED of Micro LEDs of the second color may be located in the third row, and so on, the n^{th} Micro LED of Micro LEDs of the second color may be located in the (n+1)^{th} row. The first Micro LED of Micro LEDs of the third color may be located in the first row, the second Micro LED of Micro LEDs of the third color may be located in the second row, and so on, the n^{th} Micro LED of Micro LEDs of the third color may be located in the n^{th} row.

It should be noted that in the above-disclosed embodiments, the i^{th} Micro LED of the Micro LEDs of the first color and the i^{th} Micro LED of the Micro LEDs of the second color may not be located in the same row, and the i^{th} Micro LED of the Micro LEDs of the first color and the (i+1)^{th} Micro LED of Micro LEDs of the second color may be located in the same row. Therefore, on the basis of the above-disclosed embodiments, in one embodiment, when the Micro LEDs are arranged in the second arrangement manner, the area of the first temporary substrate where the Micro LEDs are located may be larger than the area of the growth substrate. Thus, when the Micro LEDs on the growth substrate are transferred to the first temporary substrate, the first temporary substrate may accommodate full Micro LEDs in each transfer process.

It should be noted that when the Micro LED transfer method includes a second temporary substrate, and the Micro LEDs on the second temporary substrate adopt the second arrangement manner, the area of the second temporary substrate may be larger than the area of the growth substrate. When the Micro LEDs on the second temporary substrate adopt the first arrangement manner, the area of the second temporary substrate may be the same as the area of the growth substrate, which may not be limited by the present disclosure, and may be determined according to practical applications.

In another embodiment, the Micro LEDs of the at least two colors may include a plurality of columns of Micro LEDs arranged in a row direction. In the plurality of columns of Micro LEDs, a portion of adjacent columns of Micro LEDs may include Micro LEDs of different colors, and another portion of adjacent two columns of Micro LEDs may include Micro LEDs of a same color, which may not be limited by the present disclosure, and may be determined according to practical applications.

The above embodiments may be described by taking an example that one

repeating unit of the array substrate may correspond to one pixel unit of the array substrate, which may not be limited by the present disclosure. In another embodiment, one repeating unit of the array substrate may correspond to a plurality of pixel units of the array substrate, to improve the display resolution of the array substrate on the premise that the size of the array substrate is fixed.

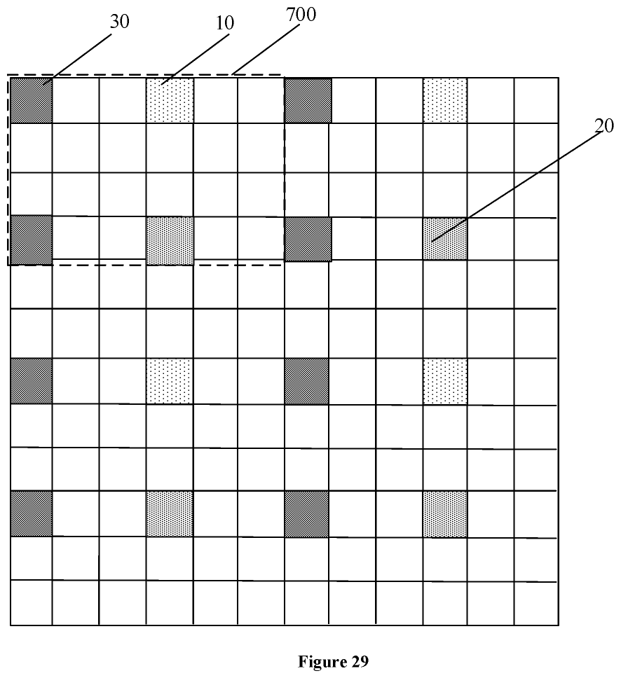

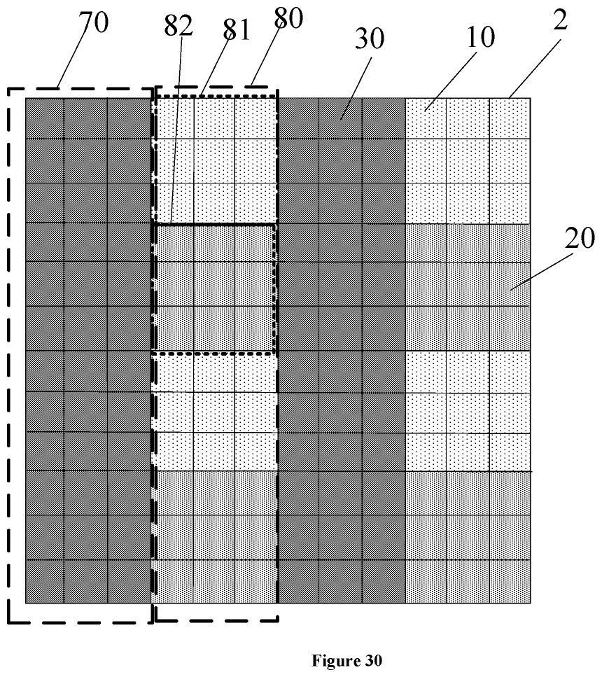

In one embodiment, the Micro LEDs of the at least two colors may include Micro LEDs of the first color, Micro LEDs of the second color, and Micro LEDs of the third color. Referring to FIG. 29, in one embodiment, the array substrate may include a plurality of repeating units. A ratio of the quantity of Micro LEDs of the first color, the quantity of Micro LEDs of the second color and the quantity of Micro LEDs of the third color in each repeating unit may be 1:1:2. In one embodiment, one repeating unit may include one Micro LED of the first color, one Micro LED of the second color, and two Micro LEDs of the third color. One repeating unit may correspond to two pixel units in the array substrate, such that on the premise that the size of the array substrate remains unchanged, the display resolution of the array substrate may be improved by allowing different pixel units to share a portion of the same Micro LEDs.

On the basis of the above-disclosed embodiments, in one embodiment, referring to FIG. 30, in the second arrangement manner, the plurality of columns of Micro LEDs may include a first composition portion 70 and a second composition portion 80 that are cyclically arranged along the row direction. The second composition portion 80 may include a first sub-composition portion 81 and a second sub-composition portion 82 that are cyclically arranged along the column direction. Each composition portion may include three columns of Micro LEDs, and each sub-composition portion may include three rows of Micro LEDs. The Micro LEDs of the first composition portion 70 may include Micro LEDs of the third color, the Micro LEDs of the first sub-composition portion 81 may include Micro LEDs of the first color, and the Micro LEDs of the second sub-composition portion 82 may include Micro LEDs of the second color, which may not be limited by the present disclosure. In another embodiment, the Micro LEDs of the at least two colors in the second arrangement manner may adopt any other arrangement, which may be determined according to practical applications.

In one embodiment, referring to FIG. 30, in the second arrangement manner, the plurality of columns of Micro LEDs may include (3j+1)^{th} column of Micro LEDs, (3j +2)^{th} column of Micro LEDs, (3j+3)^{th} column of Micro LEDs, (3j+4)^{th} column of Micro LEDs, (3j+5)^{th} column of Micro LEDs, (3j+6)^{th} column of Micro LEDs, where j may be an even number greater than and equal to zero.

The (3j+1)^{th} column of Micro LEDs may include Micro LEDs of the third color, the (3j+2)^{th} column of Micro LEDs may include Micro LEDs of the third color, and the (3j+3)^{th} column of Micro LEDs may include Micro LEDs of the third color.

In the (3j+4)^{th} column of Micro LEDs, Micro LEDs from (3k+1)^{th} row to (3k+3)^{th} row may include Micro LEDs of the first color, and Micro LEDs from the (3k+4)^{th} row to the (3k+6)^{th} row may include Micro LEDs of the second color, where k may be an even number greater than and equal to zero.

In the (3j+5)^{th} column of Micro LEDs, Micro LEDs from the (3k+1)^{th} row to the (3k+3)^{th} row may include Micro LEDs of the first color, and Micro LEDs from the (3k+4)^{th} row to the (3k+6)^{th} row may include Micro LEDs of the second color, where k may be an even number greater than and equal to zero.

In the (3j+6)^{th} column of Micro LEDs, Micro LEDs from the (3k+1)^{th} row to the

(3k+3)^{th} row may include Micro LEDs of the first color, and Micro LEDs from the (3k+4)^{th} row to the (3k+6)^{th} row may include Micro LEDs of the second color, where k may be an even number greater than and equal to zero.

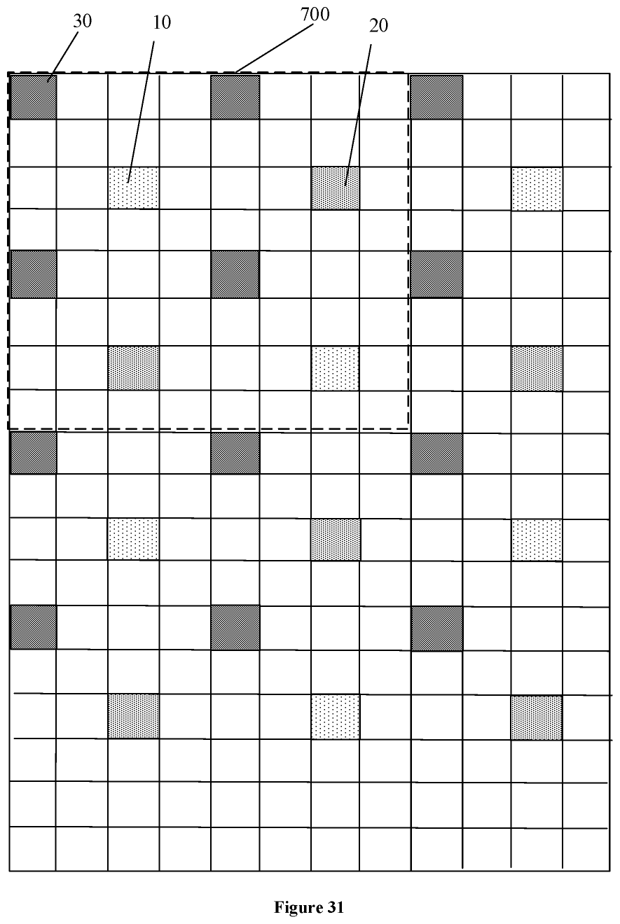

In another embodiment, referring to FIG. 31, the Micro LEDs of the at least two colors may include Micro LEDs of the first color, Micro LEDs of the second color and Micro LEDs of the third color. The array substrate may include a plurality of repeating units. A ratio of the quantity of Micro LEDs of the first color, the quantity of Micro LEDs of the second color and the quantity of Micro LEDs of the third color in each repeating unit may be 1:1:2. In one embodiment, one repeating unit may include two Micro LEDs of the first color, two Micro LEDs of the second color, and four Micro LEDs of the third color. One repeating unit may correspond to four pixel units in the array substrate, such that on the premise that the size of the array substrate remains unchanged, the display resolution of the array substrate may be improved by allowing different pixel units to share a portion of the same Micro LEDs.

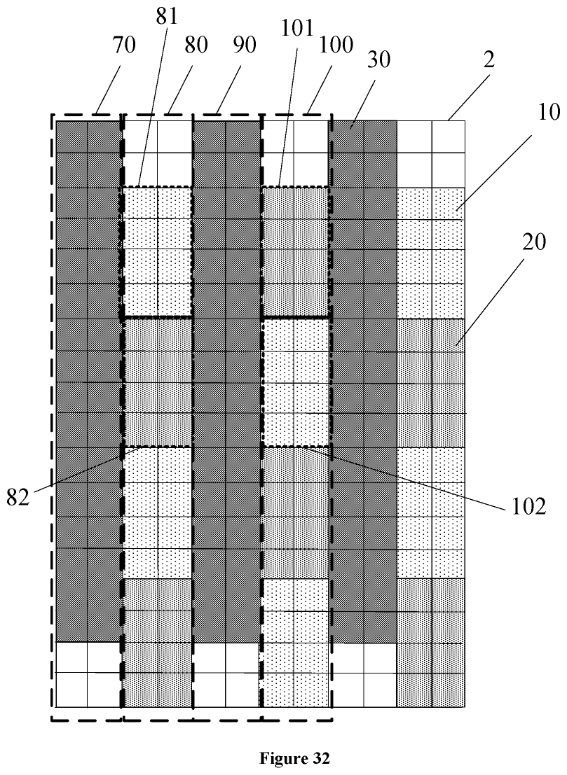

On the basis of the above-disclosed embodiments, in one embodiment, referring to FIG. 32, in the second arrangement manner, the plurality of columns of Micro LEDs may include a first composition portion 70, a second composition portion 80, a third composition portion 90, and a fourth composition portion 100 that are cyclically arranged along the row direction. The second composition portion 80 may include a first sub-composition portion 81 and a second sub-composition 82 that are cyclically arranged along the column direction. The fourth composition portion 100 may include a third sub-composition portion 101 and a fourth sub-composition portion 102 that are cyclically arranged along the column direction. Each composition portion may include two columns of Micro LEDs, and each sub-composition portion may include four rows of Micro LEDs.

The Micro LEDs of the first composition portion 70 may include Micro LEDs of the third color, the Micro LEDs of the first sub-composition portion 81 may include Micro LEDs of the first color, and the Micro LEDs of the second sub-composition portion 82 may include Micro LEDs of the second color, which may not be limited by the present disclosure. In another embodiment, the Micro LEDs of the at least two colors in the second arrangement manner may adopt any other arrangement, which may be determined according to practical applications.

In the column direction, the first composition portion 70 and the third composition portion 90 may be flush, and the second composition portion 80 and the fourth composition portion 100 may be flush. The i^{th} Micro LED of the first composition portion 70 and the i^{th} Micro LED of the second composition portion 80 may be located in different rows.

The Micro LEDs of the first composition portion 70 and the Micro LEDs of the third composition portion 90 may include Micro LEDs of the third color, the Micro LEDs of the first sub-composition portion 81 may include Micro LEDs of the first color, the Micro LEDs of the second sub-composition portion 82 may include Micro LEDs of the second color, the Micro LEDs of the third sub-composition portion 101 may include Micro LEDs of the second color, and the Micro LEDs of the fourth sub-composition portion 102 may include Micro LEDs of the first color, which may not be limited by the present disclosure. In another embodiment, the Micro LEDs of the at least two colors in the second arrangement manner may adopt any other arrangement, which may be determined according to practical applications.

In one embodiment, referring to FIG. 32, in the second arrangement manner, the plurality of columns of Micro LEDs may include (4j+1)^{th} column of Micro LEDs, (4j+2)^{th} column of Micro LEDs, (4j+3)^{th} column of Micro LEDs, (4j+4)^{th} column of Micro LEDs, (4j+5)^{th} column of Micro LEDs, (4j+6)^{th} column of Micro LEDs, (4j+7)^{th} column of Micro LEDs, and (4j+8)^{th} column of Micro LEDs, where j may be an even number greater than and equal to zero.

The (4j+1)^{th} column of Micro LEDs may include Micro LEDs of the third color, and the (4j+2)^{th} column of Micro LEDs may include Micro LEDs of the third color. The i^{th} Micro LED of the (4j+1)^{th} column of Micro LEDs and the i^{th} Micro LED of the (4j+2)^{th} column of Micro LEDs may be located in the same row, and may be located in the i^{th} row, where i may be an integer greater than or equal to one.

In the (4j+3)^{th} column of Micro LEDs, Micro LEDs from (4k+1)^{th} row to (4k+4)^{th} row may include Micro LEDs of the first color, and Micro LEDs from the (4k+5)^{th} row to the (4k+8)^{th} row may include Micro LEDs of the second color. In the (4j+4)^{th} column of Micro LEDs, Micro LEDs from the (4k+1)^{th} row to the (4k+4)^{th} row may include Micro LEDs of the first color, and Micro LEDs from the (4k+5)^{th} row to the (4k+8)^{th} row may include Micro LEDs of the second color. The i^{th} Micro LED of the (4j+3)^{th} column of Micro LEDs and the i^{th} Micro LED of the (4j+4)^{th} column of Micro LEDs may be located in the same row, and may be located in the (i+2)^{th} row. The i^{th} Micro LED of the (4j+3)^{th} column of Micro LEDs and the (i+2)^{th} Micro LED of the (4j+1)^{th} column of Micro LEDs may be located in the same row. The k may be an even number greater than and equal to zero, and i may be an integer greater than or equal to one.

The (4j+5)^{th} column of Micro LEDs may include Micro LEDs of the third color, and the (4j+6)^{th} column of Micro LEDs may include Micro LEDs of the third color. The i^{th} Micro LED of the (4j+5)^{th} column of Micro LEDs and the i^{th} Micro LED of the (4j+6)^{th} column of Micro LEDs may be located in the same row, and may be located in the i^{th} row, and the i^{th} Micro LED of the (4j+5)^{th} column of Micro LEDs and the i^{th} Micro LED of the (4j+1)^{th} column of Micro LEDs may be located in the same row, and may be located in the i^{th} row.

In the (4j+7)^{th} column of Micro LEDs, Micro LEDs from (4k+1)^{th} row to (4k+4)^{th} row may include Micro LEDs of the second color, and Micro LEDs from the (4k+5)^{th} row to the (4k+8)^{th} row may include Micro LEDs of the first color. In the (4j+8)^{th} column of Micro LEDs, Micro LEDs from the (4k+1)^{th} row to the (4k+4)^{th} row may include Micro LEDs of the second color, and Micro LEDs from the (4k+5)^{th} row to the (4k+8)^{th} row may include Micro LEDs of the first color. The i^{th} Micro LED of the (4j+7)^{th} column of Micro LEDs and the i^{th} Micro LED of the (4j+8)^{th} column of Micro LEDs may be located in the same row, and may be located in the (i+2)^{th} row.

Correspondingly, the present disclosure also provides a fabrication method of a display panel, and the display panel may include at least one display unit. The fabrication method may include following.

An array substrate may be formed. Because the fabrication method of the array substrate may be well known to those skilled in the art, the present disclosure may not describe in detail again.

Micro LEDs of various colors may be formed on the array substrate by using the Micro LED transfer method in any of the above-disclosed embodiments, to form the display unit.

In one embodiment, on the basis of the above-disclosed embodiments, in one embodiment, the display panel may include one display unit, and the display unit may be the display panel. In another embodiment, the display panel may include at least two display units to realize large-size display.

In one embodiment, when the display panel includes at least two display units, the fabrication method may further include splicing the at least two display units into a display panel, to achieve large-scale display using splicing display with multiple display units.

In addition, the present disclosure also provides a display panel formed by using the above-disclosed fabrication method of the display panel and a display device including the display panel. In one embodiment, the display device may include a mobile phone, a tablet computer, a TV, or any other device with a display function, which may not be limited by the present disclosure and may be determined according to practical applications.

Accordingly, the disclosed Micro LED transfer method and the fabrication method of the display panel in the present disclosure may include following beneficial effects. When transferring the Micro LEDs of at least two colors located on the same one first temporary substrate to at least one array substrate, Micro LEDs of the at least two colors required for the array substrate may be located on one first temporary substrate, and the Micro LEDs of the at least two colors located on the one first temporary substrate may be simultaneously transferred. Therefore, transferring the Micro LEDs of the at least two colors on the first temporary substrate to the N array substrates may merely need to be performed N times, which may greatly reduce the number of times of transferring the Micro LEDs corresponding to one array substrate. Further, the number of times of transferring the Micro LEDs in the fabrication process of the display panel including the array substrate may be greatly reduced, the transfer efficiency and transfer yield during the transfer process of the Micro LEDs may be improved. Further, the production efficiency and production yield of the display panel formed by the above-disclosed method and the display device including the display panel may be improved.

The various embodiments in the present specification are described in a progressive manner, or parallel, or progressive and juxtaposed manner. Each embodiment mainly describes in terms of differences from other embodiments, and the same or similar parts between the various embodiments may be referred to each other.

It should be noted that in the description of the present disclosure, the orientation or positional relationship indicated by the terms “upper”, “lower”, “top”, “bottom”, “inner”, “outer”, etc. is based on the orientation or positional relationship shown in the drawings, and is merely for the convenience of describing the present application and simplifying the description, rather than indicating or implying that the referred device or element must have a specific orientation, be constructed and operated in a specific orientation, and therefore should not be construed as limitations of the present disclosure. When a component is “connected” to another component, the component can be directly connected to the another component or there may be a centered component there between.

It should be noted that the relational terms such as “first” and “second” are merely used to distinguish one entity or operation from another entity or operation, and do not necessarily require or imply any such actual relationship or sequence between these entities or operations.

Moreover, the terms “include”, “contain” or any variant may be intended to cover non-exclusive inclusion, such that a process, a method, an article, or a device that includes a series of elements may not only include such elements, but also include any other element that is not clearly listed, or may include elements inherent to such process, method, article or device. In a case without more restrictions, the element defined by the sentence “including . . . ” may not exclude the existence of any other same element in the process, method, article, or device that includes the element.

The description of the disclosed embodiments is provided to illustrate the present disclosure to those skilled in the art. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments illustrated herein but is to be accorded the widest scope consistent with the principles and novel features disclosed herein.

What is claimed is:

1. A Micro LED transfer method, comprising:
transferring Micro LEDs of at least two colors from growth substrates thereof to a plurality of first temporary substrates, respectively, wherein a first temporary substrate of the plurality of first temporary substrates includes Micro LEDs of the at least two colors; and
transferring the Micro LEDs of the at least two colors located on a same first temporary substrate to at least one array substrate, wherein:
a same array substrate of the at least one array substrate includes Micro LEDs of the at least two colors, and the Micro LEDs of the at least two colors located on the same array substrate are simultaneously transferred, and
a distance between adjacent Micro LEDs of a same color on the first temporary substrate is smaller than a distance between adjacent Micro LEDs of the same color on the array substrate.

2. The Micro LED transfer method according to claim 1, wherein:
a Micro LED of the Micro LEDs of the at least two colors includes a light-emitting structure, and a first electrode and a second electrode that are electrically connected to the light-emitting structure, wherein the first electrode and the second electrode are located on a same side of the light-emitting structure.

3. The Micro LED transfer method according to claim 2, wherein transferring the Micro LEDs of the at least two colors from the growth substrates thereof to the plurality of first temporary substrates includes:
transferring the Micro LEDs of the at least two colors from the growth substrates thereof to a plurality of second temporary substrates, respectively, wherein:
on a growth substrate and a second temporary substrate of the plurality of second temporary substrates, Micro LEDs of the at least two colors are arranged according to a first arrangement manner,
on the growth substrate, both the first electrode and the second electrode of each Micro LED are located on a side of the light-emitting structure facing away from the growth substrate, and
on the second temporary substrate, both the first electrode and the second electrode of each Micro LED are located on a side of the light-emitting structure facing towards the second temporary substrate, and each second temporary substrate merely includes Micro LEDs of one color; and
transferring Micro LEDs on each second temporary substrate to the plurality of first temporary substrates, wherein:
each first temporary substrate includes Micro LEDs of the at least two colors,
Micro LEDs of a same color on each first temporary substrate are arranged according to a second arrangement manner, and the second arrangement manner is different from the first arrangement manner, and
on the first temporary substrate, both the first electrode and the second electrode of each Micro LED are located on the side of the light-emitting structure facing away from the first temporary substrate.

4. The Micro LED transfer method according to claim 2, wherein transferring the Micro LEDs of the at least two colors from the growth substrates thereof to the plurality of first temporary substrates includes:
transferring the Micro LEDs of the at least two colors from the growth substrates thereof to a plurality of second temporary substrates, respectively, wherein:
a second temporary substrate of the plurality of second temporary substrates includes Micro LEDs of the at least two colors, Micro LEDs of a same color are arranged according to a first arrangement manner on a growth substrate and are arranged according to a second arrangement manner on the second temporary substrate, and the second arrangement manner is different from the first arrangement manner, and
on the growth substrate, both the first electrode and the second electrode of each Micro LED are located on a side of the light-emitting structure facing away from the growth substrate, and
on the second temporary substrate, both the first electrode and the second electrode of each Micro LED are located on a side of the light-emitting structure facing towards the second temporary substrate; and
transferring the Micro LEDs on each second temporary substrate to a corresponding first temporary substrate of the plurality of first temporary substrates, wherein:
each first temporary substrate includes Micro LEDs of the at least two colors, and Micro LEDs of a same color are arranged according to the second arrangement manner on the first temporary substrate, and
on the first temporary substrate, both the first electrode and the second electrode of each Micro LED are located on the side of the light-emitting structure facing away from the first temporary substrate.

5. The Micro LED transfer method according to claim 1, wherein:
a Micro LED of the Micro LEDs of the at least two colors includes a light-emitting structure, and a first electrode and a second electrode that are electrically connected to the light-emitting structure, wherein the first electrode and the second electrode are located on opposite sides of the light-emitting structure.

6. The Micro LED transfer method according to claim 5, wherein transferring the Micro LEDs of the at least two colors from the growth substrates thereof to the plurality of first temporary substrates includes:
transferring the Micro LEDs of the at least two colors from the growth substrates thereof to the plurality of first temporary substrates, wherein:
the first temporary substrate includes Micro LEDs of the at least two colors, and Micro LEDs of a same color are arranged according to a first arrangement manner on the growth substrate and are arranged according to a second arrangement manner on the first temporary substrate, and the second arrangement manner is different from the first arrangement manner,
on the growth substrate, the first electrode of each Micro LED is located on a side of the light-emitting structure facing towards the growth substrate, and the second electrode of each Micro LED is located on a side of the light-emitting structure facing away from the growth substrate, and
on the first temporary substrate, the first electrode of each Micro LED is located on the side of the light-emitting structure facing away from the first temporary substrate, and the second electrode of each Micro LED is located on the side of the light-emitting structure facing towards the first temporary substrate.

7. The Micro LED transfer method according to claim 3, wherein:
in the second arrangement manner, the Micro LEDs of the at least two colors include a plurality of columns of Micro LEDs arranged in a row direction, and at least a portion of adjacent columns of Micro LEDs in the plurality of columns of Micro LEDs include Micro LEDs of different colors.

8. The Micro LED transfer method according to claim 7, wherein:
the array substrate includes a plurality of repeating units, and one repeating unit of the plurality of repeating units corresponds to one pixel unit in the array substrate,
the Micro LEDs of the at least two colors include Micro LEDs of a first color, Micro LEDs of a second color, and Micro LEDs of a third color,
a ratio of a quantity of Micro LEDs of the first color, a quantity of Micro LEDs of the second color and a quantity of Micro LEDs of the third color in each repeating unit is 1:1:1, and
Micro LEDs located in a same column in the plurality of columns of Micro LEDs include Micro LEDs of a same color.

9. The Micro LED transfer method according to claim 8, wherein:
any two adjacent columns of Micro LEDs in the plurality of columns of Micro LEDs include Micro LEDs of different colors.

10. The Micro LED transfer method according to claim 9, wherein:
the two adjacent columns of Micro LEDs in the plurality of columns of Micro LEDs are substantially center-to-center aligned in the row direction.

11. The Micro LED transfer method according to claim 9, wherein:
in the plurality of columns of Micro LEDs, at least an i^{th} Micro LEDs arranged in a column direction of Micro LEDs of two colors are located in different rows, and the i^{th} Micro LEDs arranged in the column direction of Micro LEDs of a same color are located in a same row, wherein i is a positive integer greater than or equal to one.

12. The Micro LED transfer method according to claim 11, wherein:
in the second arrangement manner, the Micro LEDs of the at least two colors include Micro LEDs of the first color, Micro LEDs of the second color, and Micro LEDs of the third color that are arranged in the row direction, wherein the Micro LEDs of the second color are located between the Micro LEDs of the first color and the Micro LEDs of the third color; and
in the column direction, the i th Micro LED of the Micro LEDs of the first color and the i^{th} Micro LED of the Micro LEDs of the third color are located in a same row, and the (i+1)^{th} Micro LED of the Micro LEDs of the first color and the i^{th} Micro LED of the Micro LEDs of the second color are located in a same row, wherein i is a positive integer greater than or equal to one.

13. The Micro LED transfer method according to claim 11, wherein:
when the Micro LEDs are arranged in the second arrangement manner, an area of the first temporary substrate where the Micro LEDs are located is larger than an area of the growth substrate.

14. The Micro LED transfer method according to claim 7, wherein:
the Micro LEDs of the at least two colors include Micro LEDs of a first color, Micro LEDs of a second color, and Micro LEDs of a third color;
the array substrate includes a plurality of repeating units, a ratio of a quantity of Micro LEDs of the first color, a quantity of Micro LEDs of the second color and a quantity of Micro LEDs of the third color in each repeating unit is 1:1:2; and
one repeating unit of the plurality of repeating units corresponds to two pixel units in the array substrate.

15. The Micro LED transfer method according to claim 14, wherein:
in the second arrangement manner, the plurality of columns of Micro LEDs include a first composition portion and a second composition portion that are cyclically arranged along the row direction, and the second composition portion includes a first sub-composition portion and a second sub-composition portion that are cyclically arranged along a column direction, wherein:
each composition portion includes three columns of Micro LEDs, and each sub-composition portion includes three rows of Micro LEDs, and
the Micro LEDs of the first composition portion include Micro LEDs of the third color, the Micro LEDs of the first sub-composition portion include Micro LEDs of the first color, and the Micro LEDs of the second sub-composition portion include Micro LEDs of the second color.

16. The Micro LED transfer method according to claim 7, wherein:
the Micro LEDs of the at least two colors include Micro LEDs of a first color, Micro LEDs of a second color, and Micro LEDs of a third color;
the array substrate includes a plurality of repeating units, a ratio of a quantity of Micro LEDs of the first color, a quantity of Micro LEDs of the second color and a quantity of Micro LEDs of the third color in each repeating unit is 1:1:2; and
one repeating unit of the plurality of repeating units corresponds to four pixel units in the array substrate.

17. The Micro LED transfer method according to claim 16, wherein:
in the second arrangement manner, the plurality of columns of Micro LEDs include a first composition portion, a second composition portion, a third composition portion, and a fourth composition portion that are cyclically arranged along the row direction, wherein:
the second composition portion includes a first sub-composition portion and a second sub-composition portion that are cyclically arranged along a column direction, and the fourth composition portion includes a third sub-composition portion and a fourth sub-composition portion that are cyclically arranged along the column direction,
each composition portion includes two columns of Micro LEDs, and each sub-composition portion includes four rows of Micro LEDs,
in the column direction, the first composition portion and the third composition portion are flush, and the second composition portion and the fourth composition portion are flush,
the i^{th} Micro LED of the first composition portion and the i^{th} Micro LED of the second composition portion are located in different rows, and
the Micro LEDs of the first composition portion and the Micro LEDs of the third composition portion include Micro LEDs of the third color, the Micro LEDs of the first sub-composition portion includes Micro LEDs of the first color, the Micro LEDs of the second sub-composition portion includes Micro LEDs of the second color, the Micro LEDs of the third sub-composition portion includes Micro LEDs of the second color, and the Micro LEDs of the fourth sub-composition portion includes Micro LEDs of the first color.

18. A fabrication method of a display panel, wherein the display panel includes at least one display unit, and the fabrication method comprising:
forming an array substrate, and
forming Micro LEDs of various colors on the array substrate by using a Micro LED transfer method to form the display unit, the Micro LED transfer method including:
transferring Micro LEDs of at least two colors from growth substrates thereof to a plurality of first temporary substrates, respectively, wherein a first temporary substrate of the plurality of first temporary substrates includes Micro LEDs of the at least two colors; and
transferring the Micro LEDs of the at least two colors located on a same first temporary substrate to at least one array substrate, wherein:
a same array substrate of the at least one array substrate includes Micro LEDs of the at least two colors, and the Micro LEDs of the at least two colors located on the same array substrate are simultaneously transferred, and
a distance between adjacent Micro LEDs of a same color on the first temporary substrate is smaller than a distance between adjacent Micro LEDs of the same color on the array substrate.

19. The fabrication method according to claim 18, wherein:
the display panel includes at least two display units, and the fabrication method further includes:
splicing the at least two display units into the display panel.

20. A display panel, wherein the display panel is formed by a fabrication method, the fabrication method including:
forming an array substrate, and
forming Micro LEDs of various colors on the array substrate by using a Micro LED transfer method to form the display unit, the Micro LED transfer method including:
transferring Micro LEDs of at least two colors from growth substrates thereof to a plurality of first temporary substrates, respectively, wherein a first temporary substrate of the plurality of first temporary substrates includes Micro LEDs of the at least two colors; and
transferring the Micro LEDs of the at least two colors located on a same first temporary substrate to at least one array substrate, wherein:
a same array substrate of the at least one array substrate includes Micro LEDs of the at least two colors, and the Micro LEDs of the at least two colors located on the same array substrate are simultaneously transferred, and
a distance between adjacent Micro LEDs of a same color on the first temporary substrate is smaller than a distance between adjacent Micro LEDs of the same color on the array substrate.
